(19) United States
(12) Patent Application Publication
(10) Pub. No.: US 2025/0374635 A1
(43) Pub. Date: Dec. 4, 2025

(54) SEMICONDUCTOR DEVICE

(71) Applicant: Samsung Electronics Co., Ltd., Suwon-si (KR)

(72) Inventors: Hyung Goo Lee, Suwon-si (KR); Gwan Ho Kim, Suwon-si (KR); Sung Woo Kang, Suwon-si (KR); Kyong Beom Koh, Suwon-is (KR)

(21) Appl. No.: 19/020,588

(22) Filed: Jan. 14, 2025

(30) Foreign Application Priority Data
May 30, 2024 (KR) 10-2024-0070886

(51) Int. Cl. H10D 64/23; H10D 30/00; H10D 30/01; H10D 30/43; H10D 62/10; H10D 62/13; H10D 84/01; H10D 84/83

(52) U.S. Cl. CPC H10D 64/251; H10D 30/43; H10D 30/501; H10D 62/116; H10D 62/121; H10D 62/151; H10D 84/832; H10D 30/014; H10D 30/0191; H10D 84/013; H10D 84/0149

(57) ABSTRACT

A semiconductor device includes a lower interlayer insulating layer, an active pattern spaced, a plurality of nanosheets, a gate electrode, a source/drain region, a liner layer, a contact isolation layer, and a source/drain contact, where the sidewall of the contact isolation layer includes a first sidewall in contact with the source/drain contact in the first horizontal direction, a second sidewall in contact with each of the liner layer and the active pattern in the first horizontal direction, and a vertex between the first sidewall and the second sidewall, and where a slope profile of the first sidewall of the contact isolation layer and a slope profile of the second sidewall of the contact isolation layer are different.

### CROSS-REFERENCE TO RELATED APPLICATION

This application claims priorities from Korean Patent Application No. 10-2024-0070886 filed on May 30, 2024 in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor device. Specifically, the present disclosure relates to a semiconductor device including a MBCFET™ (Multi-Bridge Channel Field Effect Transistor).

### BACKGROUND

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, they are relatively easy to scale. Additionally, the current control capability may be improved without increasing the gate length of the multi-gate transistor. Furthermore, the SCE (short channel effect) in which the potential of the channel region is affected by the drain voltage may be effectively suppressed.

### SUMMARY

Aspects of the present disclosure provide a semiconductor device with improved reliability of the source/drain contacts formed in the lower part of the source/drain region.

The aspects of the present disclosure are not limited to those mentioned above and another aspect which is not mentioned may be clearly understood by those skilled in the art from the description below.

According to some embodiments of the present disclosure, there is provided a semiconductor device, comprising a lower interlayer insulating layer; an active pattern spaced apart from an upper surface of the lower interlayer insulating layer in a vertical direction that is perpendicular to the upper surface of the lower interlayer insulating layer, the active pattern extending in a first horizontal direction that is parallel to the upper surface of the lower interlayer insulating layer, the active pattern including silicon (Si), a plurality of nanosheets that are on the active pattern and spaced apart from each other in the vertical direction; a gate electrode on the active pattern and extending in a second horizontal direction that is parallel to the upper surface of the lower interlayer insulating layer and intersects the first horizontal direction, the gate electrode surrounding at least a portion of the plurality of nanosheets; a source/drain region that is on a first side of the gate electrode and is on the active pattern; a liner layer in contact with a lower surface of the active pattern, the liner layer spaced apart from the upper surface of the lower interlayer insulating layer in the vertical direction, the liner layer including an insulating material; a contact isolation layer on a lower part of the gate electrode. the contact isolation layer extending from the upper surface of the lower interlayer insulating layer to an uppermost surface of the active pattern in the vertical direction; and a source/drain contact between the upper surface of the lower interlayer insulating layer and the source/drain region, the source/drain contact electrically connected to the source/drain region, the source/drain contact including a first portion in contact with a sidewall of the contact isolation layer in the first horizontal direction, the source/drain contact including a second portion extending into the source/drain region, the liner layer, and the active pattern in the vertical direction, the second portion of the source/drain contact on an upper surface of the first portion of the source/drain contact, where the sidewall of the contact isolation layer includes a first sidewall in contact with the source/drain contact in the first horizontal direction, a second sidewall in contact with each of the liner layer and the active pattern in the first horizontal direction, and a vertex between the first sidewall and the second sidewall, and where a slope profile of the first sidewall of the contact isolation layer and a slope profile of the second sidewall of the contact isolation layer are different.

According to some embodiments of the present disclosure, there is provided a semiconductor device, comprising a lower interlayer insulating layer; an active pattern spaced apart from an upper surface of the lower interlayer insulating layer in a vertical direction that is perpendicular to the upper surface of the lower interlayer insulating layer, the active pattern extending in a first horizontal direction that is parallel to the upper surface of the lower interlayer insulating layer, the active pattern including silicon (Si); a first gate electrode on the active pattern and extending in a second horizontal direction that is parallel to the upper surface of the lower interlayer insulating layer and intersects the first horizontal direction, a second gate electrode extending in the second horizontal direction and on the active pattern, the second gate electrode spaced apart from the first gate electrode in the first horizontal direction, a source/drain region that is between the first gate electrode and the second gate electrode and is on the active pattern; a liner layer in contact with a lower surface of the active pattern, the liner layer spaced apart from the upper surface of the lower interlayer insulating layer in the vertical direction, the liner layer including an insulating material; a first contact isolation layer on a lower part of the first gate electrode, the first contact isolation layer extending from the upper surface of the lower interlayer insulating layer to an uppermost surface of the active pattern in the vertical direction; a second contact isolation layer on a lower part of the second gate electrode, the second contact isolation layer extending from the upper surface of the lower interlayer insulating layer to the uppermost surface of the active pattern in the vertical direction, the second contact isolation layer spaced apart from the first contact isolation layer in the first horizontal direction; and a source/drain contact between the upper surface of the lower interlayer insulating layer and the source/drain region, the source/drain contact electrically connected to the source/drain region, the source/drain contact including a first portion in contact with sidewalls of each of the first contact isolation layer and the second contact isolation layer in the first horizontal direction, the source/drain contact including a second portion extending into the source/drain region, the liner layer, and the active pattern in the vertical direction, the second portion of the source/drain contact on an upper surface of the first portion of the source/drain contact. The sidewall of the first contact isolation layer includes a first sidewall in contact with the source/drain contact in the first horizontal direction, a second sidewall in contact with each of the liner layer and the active pattern in the first horizontal direction, and a vertex between the first sidewall and the second sidewall, a slope profile of the first sidewall of the first contact isolation layer and a slope profile of the second sidewall of the first contact isolation layer are different, and at least a portion of the upper surface of the first portion of the source/drain contact is in contact with a lower surface of the liner layer in the vertical direction.

According to some embodiments of the present disclosure, there is provided a semiconductor device, comprising a lower interlayer insulating layer; an active pattern spaced apart from an upper surface of the lower interlayer insulating layer in a vertical direction that is perpendicular to the upper surface of the lower interlayer insulating layer, the active pattern extending in a first horizontal direction that is parallel to the upper surface of the lower interlayer insulating layer, the active pattern including silicon (Si); a plurality of nanosheets that are on the active pattern and spaced apart from each other in the vertical direction; a gate electrode on the active pattern and extending in a second horizontal direction that is parallel to the upper surface of the lower interlayer insulating layer and intersects the first horizontal direction, the gate electrode surrounding at least a portion of the plurality of nanosheets; a source/drain region that is on a first side of the gate electrode and is on the active pattern; a liner layer in contact with a lower surface of the active pattern, the liner layer spaced apart from the upper surface of the lower interlayer insulating layer in the vertical direction, the liner layer including an insulating material, a gate insulating layer that is between the active pattern and the gate electrode and is between the plurality of nanosheets and the gate electrode, the gate insulating layer spaced apart from the liner layer in the vertical direction; a contact isolation layer on a lower part of the gate electrode, the contact isolation layer extending from the upper surface of the lower interlayer insulating layer to an uppermost surface of the active pattern in the vertical direction, an upper surface of the contact isolation layer being in contact with the gate insulating layer in the vertical direction; a source/drain contact between the upper surface of the lower interlayer insulating layer and the source/drain region, the source/drain contact electrically connected to the source/drain region, the source/drain contact including a first portion in contact with a sidewall of the contact isolation layer in the first horizontal direction, source/drain contact including a second portion extending into the source/drain region, the liner layer, and the active pattern in the vertical direction, the second portion of the source/drain contact on an upper surface of the first portion of the source/drain contact; a silicide layer between the source/drain contact and the source/drain region, a lower surface of the silicide layer in contact with the active pattern in the vertical direction; and a field insulating layer that is on the upper surface of the lower interlayer insulating layer and in contact with the sidewalls of each of the contact isolation layer, the first portion of the source/drain contact, the liner layer and the active pattern in the second horizontal direction. The sidewall of the contact isolation layer includes a first sidewall in contact with the source/drain contact in the first horizontal direction, a second sidewall in contact with each of the source/drain contact, the liner layer, and the active pattern in the first horizontal direction, and a vertex between the first sidewall and the second sidewall, the vertex is on a sidewall of the first portion of the source/drain contact in the first horizontal direction, a slope profile of the first sidewall of the contact isolation layer and a slope profile of the second sidewall of the contact isolation layer are different, and at least a portion of the upper surface of the first portion of the source/drain contact is in contact with a lower surface of the liner layer in the vertical direction

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a layout diagram for explaining a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIGS. 5 to 43 are intermediate stage diagrams for explaining methods of fabricating semiconductor devices according to some embodiments of the present disclosure;

FIG. 44 is a cross-sectional view for explaining a semiconductor device according to some embodiments of the present disclosure;

FIG. 45 is a cross-sectional view for explaining a semiconductor device according to some embodiments of the present disclosure; and

FIG. 46 is a cross-sectional view for explaining a semiconductor device according to some embodiments of the present disclosure.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection.

In the following drawings of a semiconductor device according to some embodiments, by way of example, the semiconductor device is described as including a transistor (MBCFET™ (Multi-Bridge Channel Field Effect Transistor)) that includes a nanosheet. However, the present disclosure is not limited thereto. In some embodiments, the semiconductor device may include a fin-shaped transistor (FinFET) that includes a fin-shaped pattern channel region, a tunneling transistor (tunneling FET), or a three-dimensional (3D) transistor. Additionally, the semiconductor device according to some embodiments may include a bipolar junction transistor or a lateral double-diffused metal-oxide-semiconductor (LDMOS) transistor.

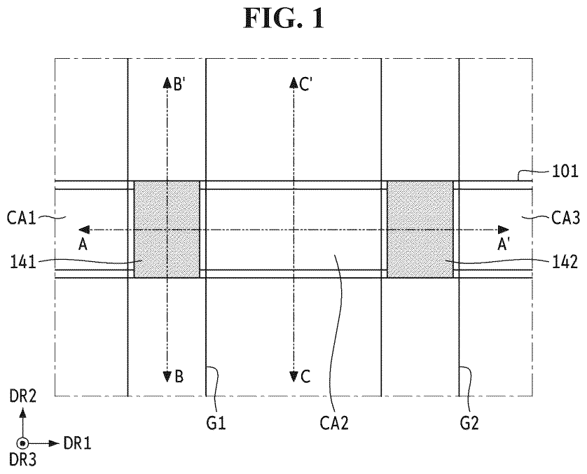

Hereinafter, a semiconductor device according to some embodiments of the present disclosure will be described with reference to FIGS. 1 to 4.

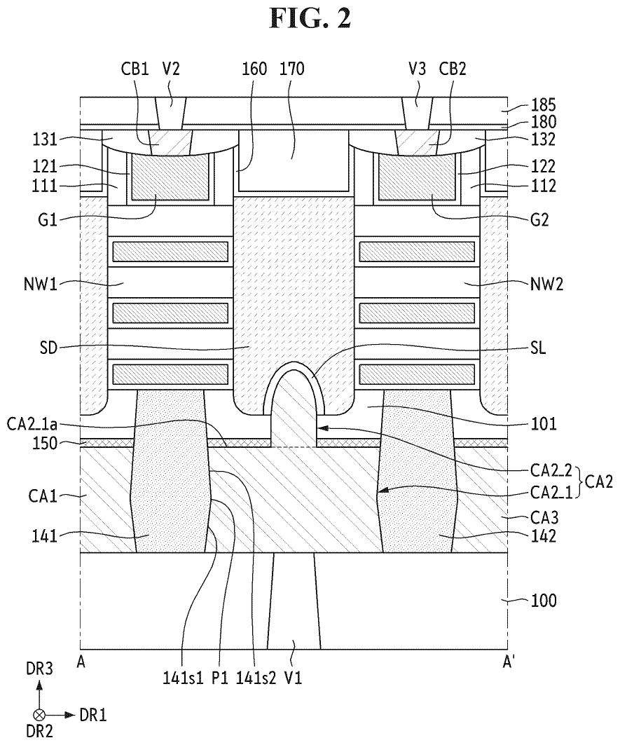

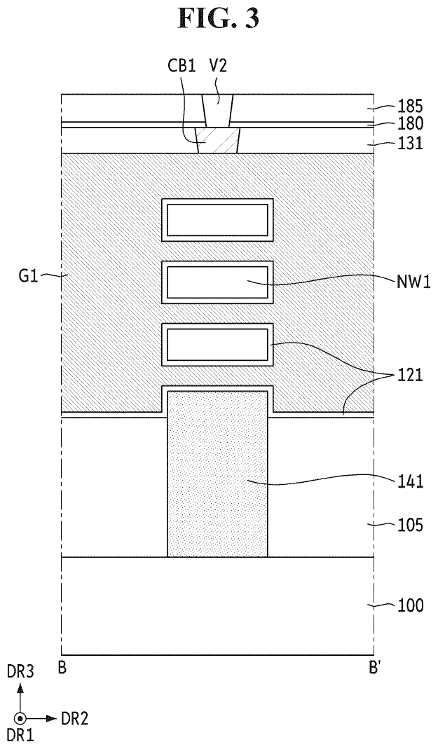

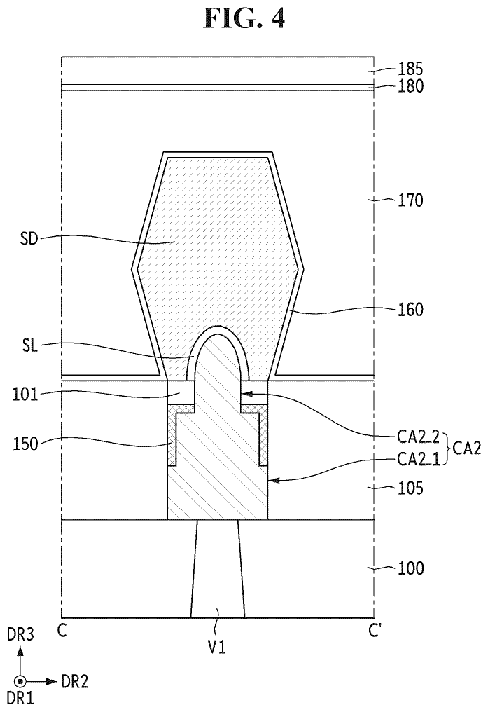

FIG. 1 is a layout diagram for explaining a semiconductor device according to some embodiments of the present disclosure. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1.

Referring to FIGS. 1 to 4, a semiconductor device according to some embodiments of the present disclosure includes a lower interlayer insulating layer 100, an active pattern 101, a field insulating layer 105, first and second plurality of nanosheets NW1, NW2, first and second gate electrodes G1, G2, first and second gate spacers 111, 112, first and second gate insulating layers 121, 122, first and second capping patterns 131, 132, a source/drain region SD, first and second contact isolation layers 141, 142, first to third source/drain contacts CA1, CA2, CA3, a silicide layer SL, a liner layer 150, a first etch stop layer 160, a first upper interlayer insulating layer 170, first and second gate contacts CB1, CB2, a second etch stop layer 180, a second upper interlayer insulating layer 185, and first to third vias V1, V2, V3.

The lower interlayer insulating layer 100 may include, for example, at least one of silicon oxide, silicon nitride, silicon oxynitride, and low-k materials. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof, but the present disclosure is not limited thereto.

Hereinafter, the first horizontal direction DR1 and the second horizontal direction DR2 may each be defined as directions parallel to the upper surface of the lower interlayer insulating layer 100. The second horizontal direction DR2 may be defined as a direction different from (or intersecting) the first horizontal direction DR1. The vertical direction DR3 may be defined as a direction perpendicular to each of the first horizontal direction DR1 and the second horizontal direction DR2. In other words, the vertical direction DR3 may be defined as a direction perpendicular to the upper surface of the lower interlayer insulating layer 100.

The active pattern 101 may extend in the first horizontal direction DR1 on the upper surface of the lower interlayer insulating layer 100. For example, the active pattern 101 may be spaced apart from the upper surface of the lower interlayer insulating layer 100 in the vertical direction DR3. For example, the active pattern 101 may include silicon (Si). The field insulating layer 105 may be disposed on the upper surface of the lower interlayer insulating layer 100.

For example, the field insulating layer 105 may at least partially surround the sidewalls of the active pattern 101. For example, the field insulating layer 105 may be in contact with the sidewalls of the active pattern 101 in the second horizontal direction DR2. For example, the field insulating layer 105 may be in contact with the sidewalls of each of the first contact isolation layer 141, the second contact isolation layer 142, the first portion CA2_1 of the source/drain contact CA2, and the liner layer 150 in the second horizontal direction DR2. Detailed descriptions of each of the first contact isolation layer 141, the second contact isolation layer 142, the first portion CA2_1 of the source/drain contact CA2, and the liner layer 150 will be described later. The field insulating layer 105 may include, for example, an oxide layer, a nitride layer, an oxynitride layer, or a combination thereof.

The first plurality of nanosheets NW1 may be disposed on the upper surface of the active pattern 101. The first plurality of nanosheets NW1 may be disposed at the intersection of the active pattern 101 and the first gate electrode G1. The second plurality of nanosheets NW2 may be disposed on the upper surface of the active pattern 101. The second plurality of nanosheets NW2 may be disposed at the intersection of the active pattern 101 and the second gate electrode G2. The second plurality of nanosheets NW2 may be spaced apart from the first plurality of nanosheets NW1 in the first horizontal direction DR1.

For example, each of the first and second plurality of nanosheets NW1, NW2 may include a plurality of nanosheets stacked and spaced apart from each other in the vertical direction DR3. In FIGS. 2 and 3, each of the first and second plurality of nanosheets NW1, NW2 is shown as including three nanosheets stacked and spaced apart from each other in the vertical direction DR3, but this is for convenience of explanation and the present disclosure is not limited thereto. In some embodiments, each of the first and second plurality of nanosheets NW1, NW2 may include four or more nanosheets stacked and spaced apart from each other in the vertical direction DR3. For example, each of the first and second plurality of nanosheets NW1, NW2 may include silicon (Si).

The first gate electrode G1 may extend on the active pattern 101 and the field insulating layer 105 in the second horizontal direction DR2. The first gate electrode G1 may surround at least a portion of the first plurality of nanosheets NW1. The second gate electrode G2 may extend on the active pattern 101 and the field insulating layer 105 in the second horizontal direction DR2. The second gate electrode G2 may surround at least a portion of the second plurality of nanosheets NW2. The second gate electrode G2 may be spaced apart from the first gate electrode G1 in the first horizontal direction DR1.

Each of the first and second gate electrodes G1, G2 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAIN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof. Each of the first and second gate electrodes G1, G2 may include conductive metal oxides, conductive metal oxynitrides, or the like, and may also include an oxidized form of the above-described materials.

The first gate spacer 111 may extend along both sidewalls of the first gate electrode G1 in the second horizontal direction DR2 on the upper surface of the uppermost nanosheet of the first plurality of nanosheets NW1 and on the field insulating layer 105. The second gate spacer 112 may extend along both sidewalls of the second gate electrode G2 in the second horizontal direction DR2 on the upper surface of the uppermost nanosheet of the second plurality of nanosheets NW2 and on the field insulating layer 105. Each of the first and second gate spacers 111, 112 may include at least one of, for example, silicon nitride (SiN), silicon oxynitride (SiON), silicon oxide (SiO₂), silicon carbonitride (SiOCN), silicon boron nitride (SiBN), silicon oxyboron nitride (SiOBN), silicon oxycarbide (SiOC), and combinations thereof. However, the present disclosure is not limited thereto.

The source/drain region SD may be disposed on both sides of each of the first and second gate electrodes G1, G2 on the upper surface of the active pattern 101. For example, the source/drain region SD may be disposed between the first gate electrode G1 and the second gate electrode G2 on the upper surface of the active pattern 101. For example, the source/drain region SD may be in contact with the upper surface of the active pattern 101. For example, the source/drain region SD may be in contact with each of the sidewalls of the first plurality of nanosheets NW1 in the first horizontal direction DR1 and the sidewalls of the second plurality of nanosheets NW2 in the first horizontal direction DR1. For example, the upper surface of the source/drain region SD may be formed to be higher than the upper surface of the uppermost nanosheets of each of the first and second plurality of nanosheets NW1, NW2. As used herein, a surface A that is “formed to be higher” than surface B refers to a height of surface A relative to another element, such as, for example, the upper surface of the interlayer insulating layer 100 in the vertical direction being greater than a height of surface B relative to the upper surface of the interlayer insulating layer 100 in the vertical direction. As used herein, a surface A that is “formed to be lower” than surface B refers to a height of surface A relative to another element, such as, for example, the upper surface of the interlayer insulating layer 100 in the vertical direction being less than a height of surface B relative to the upper surface of the interlayer insulating layer 100 in the vertical direction.

The first gate insulating layer 121 may be disposed between the first gate electrode G1 and the active pattern 101. The first gate insulating layer 121 may be disposed between the first gate electrode G1 and the field insulating layer 105. The first gate insulating layer 121 may be disposed between the first gate electrode G1 and the first gate spacer 111. The first gate insulating layer 121 may be disposed between the first gate electrode G1 and the first plurality of nanosheets NW1. The first gate insulating layer 121 may be disposed between the first gate electrode G1 and the source/drain region SD. For example, the first gate insulating layer 121 may be disposed between the first gate electrode G1 and the upper surface of the first contact isolation layer 141.

The second gate insulating layer 122 may be disposed between the second gate electrode G2 and the active pattern 101. The second gate insulating layer 122 may be disposed between the second gate electrode G2 and the field insulating layer 105. The second gate insulating layer 122 may be disposed between the second gate electrode G2 and the second gate spacer 112. The second gate insulating layer 122 may be disposed between the second gate electrode G2 and the second plurality of nanosheets NW2. The second gate insulating layer 122 may be disposed between the second gate electrode G2 and the source/drain region SD. For example, the second gate insulating layer 122 may be disposed between the second gate electrode G2 and the upper surface of the second contact isolation layer 142.

Each of the first and second gate insulating layers 121, 122 may include at least one of silicon oxide, silicon oxynitride, silicon nitride, or a high-k material having a dielectric constant greater than that of silicon oxide. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some embodiments may include a NC (Negative Capacitance) FET utilizing a negative capacitor. For example, each of the first and second gate insulating layers 121, 122 may include a ferroelectric material layer with ferroelectric properties and a paraelectric material layer with paraelectric properties.

The ferroelectric material layer may have a negative capacitance, while the paraelectric material layer may have a positive capacitance. For example, if two or more capacitors are connected in series and each capacitor has a positive capacitance, the total capacitance may be less than the capacitance of each individual capacitor. On the other hand, if at least one of the capacitances of the two or more capacitors connected in series has a negative value, the total capacitance may have a positive value and be greater than the absolute value of each individual capacitance.

When the ferroelectric material layer with a negative capacitance and the paraelectric material layer with a positive capacitance are connected in series, the total capacitance value of the ferroelectric material layer and the paraelectric material layer connected in series may be increased. By utilizing the increase in total capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and lead zirconium titanium oxide. For example, hafnium zirconium oxide may be a material in which zirconium (Zr) is doped into hafnium oxide. In another example, hafnium zirconium oxide may be a compound of hafnium (Hf), zirconium (Zr), and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). Depending on which ferroelectric material the ferroelectric material layer includes, the type of dopant included in the ferroelectric material layer may vary.

If the ferroelectric material layer includes hafnium oxide, the dopant included in the ferroelectric material layer may include, for example, at least one of gadolinium (Gd), silicon (Si), zirconium (Zr), aluminum (Al), and yttrium (Y).

If the dopant is aluminum (Al), the ferroelectric material layer may include 3 to 8 at % (atomic %) of aluminum. Here, the ratio of the dopant may be a ratio of aluminum to the sum of hafnium and/or aluminum.

If the dopant is silicon (Si), the ferroelectric material layer may include 2 to 10 at % of silicon. If the dopant is yttrium (Y), the ferroelectric material layer may include 2 to 10 at % of yttrium. If the dopant is gadolinium (Gd), the ferroelectric material layer may include 1 to 7 at % of gadolinium. If the dopant is zirconium (Zr), the ferroelectric material layer may include 50 to 80 at % of zirconium.

The paraelectric material layer may have paraelectric properties. The paraelectric material layer may include, for example, at least one of silicon oxide and a metal oxide with a high dielectric constant. The metal oxide included in the paraelectric material layer may include, for example, at least one of hafnium oxide, zirconium oxide, and/or aluminum oxide, but is not limited thereto.

The ferroelectric material layer and the paraelectric material layer may include the same material. The ferroelectric material layer may have ferroelectric properties, while the paraelectric material layer may not have ferroelectric properties. For example, if the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. The thickness of the ferroelectric material layer may be, for example, 0.5 to 10 nm, but is not limited thereto. Since each ferroelectric material may have a different critical thickness that exhibits ferroelectric properties, the thickness of the ferroelectric material layer may vary depending on the ferroelectric material.

As an example, each of the first and second gate insulating layers 121, 122 may include a single ferroelectric material layer. In another example, each of the first and second gate insulating layers 121, 122 may include a plurality of ferroelectric material layers spaced apart from each other. Each of the first and second gate insulating layers 121, 122 may have a stacked structure in which the plurality of ferroelectric material layers and the plurality of paraelectric material layers are alternately stacked.

The liner layer 150 may be disposed on the lower surface of the active pattern 101. For example, the upper surface of the liner layer 150 may be in contact with the lower surface of the active pattern 101. For example, the liner layer 150 may be formed conformally on the lower surface of the active pattern 101. For example, the liner layer 150 may be spaced apart from the upper surface of the lower interlayer insulating layer 100 in the vertical direction DR3. For example, the source/drain region SD may be spaced apart from the upper surface of the liner layer 150 in the vertical direction DR3. For example, the active pattern 101 may be disposed between the upper surface of the liner layer 150 and the lower surface of the source/drain region SD. The active pattern 101 may be disposed between the upper surface of the liner layer 150 and the first gate electrode G1. The active pattern 101 may be disposed between the upper surface of the liner layer 150 and the second gate electrode G2.

For example, the sidewalls of the liner layer 150 in the second horizontal direction DR2 may be in contact with the field insulating layer 105. For example, at least a portion of the liner layer 150 may extend along the sidewalls of the field insulating layer 105 in the vertical direction DR3. For example, the upper surface of the liner layer 150 may be formed to be lower than the upper surface of the field insulating layer 105. The liner layer 150 may include an insulating material. For example, the liner layer 150 may include at least one of silicon nitride (SiN), silicon oxynitride (SiON), silicon carbonitride (SiCN), silicon oxycarbonitride (SiOCN), and/or combinations thereof. However, the present disclosure is not limited thereto.

The first contact isolation layer 141 may be disposed on the upper surface of the lower interlayer insulating layer 100. The first contact isolation layer 141 may be disposed on the lower part of the first gate electrode G1. For example, the first contact isolation layer 141 may extend from the upper surface of the lower interlayer insulating layer 100 to the uppermost surface of the active pattern 101 in the vertical direction DR3. In other words, the first contact isolation layer 141 may penetrate or extend into each of the liner layer 150 and the active pattern 101 in the vertical direction DR3. For example, the sidewalls of the first contact isolation layer 141 in the first horizontal direction DR1 may be in contact with each of the liner layer 150 and the active pattern 101.

For example, the lower surface of the first contact isolation layer 141 may be in contact with the upper surface of the lower interlayer insulating layer 100. For example, the upper surface of the first contact isolation layer 141 may be in contact with the first gate insulating layer 121. For example, the upper surface of the first contact isolation layer 141 may be formed on the same plane as the uppermost surface of the active pattern 101, but the present disclosure is not limited thereto. For example, the upper surface of the first contact isolation layer 141 may be formed to be higher than the upper surface of the liner layer 150.

For example, the sidewalls of the first contact isolation layer 141 in the first horizontal direction DR1 may include a first sidewall 141s1, a second sidewall 141s2, and an inflection point or vertex P1 where the first sidewall 141s1 and the second sidewall 141s2 are connected. In some embodiments, the vertex P1 may be a point along the sidewall of the first contact isolation layer 141 in which the sign of the slope in the first direction D1 changes (e.g., the first sidewall 141s1 and the second sidewall 141s2 have different signs in the first direction D1). For example, the vertex P1 may be formed between the upper surface of the lower interlayer insulating layer 100 and the liner layer 150. That is, the first sidewall 141s1 of the first contact isolation layer 141 may be formed between the upper surface of the lower interlayer insulating layer 100 and the liner layer 150. The second sidewall 141s2 of the first contact isolation layer 141 may be in contact with each of the liner layer 150 and the active pattern 101.

For example, the slope profile of the first sidewall 141s1 of the first contact isolation layer 141 and the slope profile of the second sidewall 141s2 of the first contact isolation layer 141 may be formed differently based on the vertex P1. For example, the slope profile of the first sidewall 141s1 of the first contact isolation layer 141 may have a slope such that a distance in the first direction D1 between the first sidewall 141s1 and the center of the first contact isolation layer 141 gradually increases as it approaches the vertex Pl (e.g., the first sidewall 141s1 has a positive slope in the first direction D1). For example, the slope profile of the second sidewall 141s2 of the first contact isolation layer 141 may have a slope such that a distance in the first direction D1 between the second sidewall 141s2 and the center of the first contact isolation layer 141 decreases as it approaches the vertex P1 (e.g., the first sidewall 141s2 has a negative slope in the first direction D1). For example, both sidewalls of the first contact isolation layer 141 in the second horizontal direction DR2 may be in contact with the field insulating layer 105. For example, the upper surface of the first contact isolation layer 141 may be formed to be higher than the upper surface of the field insulating layer 105. For example, the lower surface of the first contact isolation layer 141 may be formed on the same plane as the lower surface of the field insulating layer 105.

The second contact isolation layer 142 may be disposed on the upper surface of the lower interlayer insulating layer 100. The second contact isolation layer 142 may be disposed on the lower part of the second gate electrode G2. The second contact isolation layer 142 may be spaced apart from the first contact isolation layer 141 in the first horizontal direction DR1. For example, the second contact isolation layer 142 may extend from the upper surface of the lower interlayer insulating layer 100 to the uppermost surface of the active pattern 101 in the vertical direction DR3. In other words, the second contact isolation layer 142 may penetrate or extend into each of the liner layer 150 and the active pattern 101 in the vertical direction DR3. For example, the sidewall of the second contact isolation layer 142 in the first horizontal direction DR1 may be in contact with each of the liner layer 150 and the active pattern 101.

For example, the lower surface of the second contact isolation layer 142 may be in contact with the upper surface of the lower interlayer insulating layer 100. For example, the upper surface of the second contact isolation layer 142 may be in contact with the second gate insulating layer 122. For example, the upper surface of the second contact isolation layer 142 may be formed on the same plane as the uppermost surface of the active pattern 101, but the present disclosure is not limited thereto. For example, the upper surface of the second contact isolation layer 142 may be formed to be higher than the upper surface of the liner layer 150. For example, the shape of the sidewalls of the second contact isolation layer 142 may be the same as the shape of the sidewalls of the first contact isolation layer 141. Accordingly, a detailed description of the shape of the sidewalls of the second contact isolation layer 142 is omitted.

For example, each of the first and second contact isolation layers 141, 142 may include silicon oxide (SiO₂). In some embodiments, each of the first and second contact isolation layers 141, 142 may include titanium oxide (TiO₂) or silicon nitride (SiN). For example, each of the first and second contact isolation layers 141, 142 may include the same material as the liner layer 150, but the present disclosure is not limited thereto.

Each of the first to third source/drain contacts CA1, CA2, CA3 may be disposed between the upper surface of the lower interlayer insulating layer 100 and the lower surface of the liner layer 150. For example, the second source/drain contact CA2 may be spaced apart from the first source/drain contact CA1 in the first horizontal direction DR1. The first and second source/drain contacts CA1, CA2 may be separated in the first horizontal direction DR1 by the first contact isolation layer 141. For example, the third source/drain contact CA3 may be spaced apart from the second source/drain contact CA2 in the first horizontal direction DR1. The second and third source/drain contacts CA2, CA3 may be separated in the first horizontal direction DR1 by the second contact isolation layer 142. For example, each of the first to third source/drain contacts CA1, CA2, CA3 may have a similar structure. Accordingly, the following description will focus on the second source/drain contact CA2, and detailed descriptions of the first and third source/drain contacts CA1, CA3 will be omitted.

The second source/drain contact CA2 may be disposed between the upper surface of the lower interlayer insulating layer 100 and the source/drain region SD. For example, the lower surface of the second source/drain contact CA2 may be in contact with the upper surface of the lower interlayer insulating layer 100. The second source/drain contact CA2 may be disposed between the first contact isolation layer 141 and the second contact isolation layer 142. For example, both sidewalls of the second source/drain contact CA2 in the first horizontal direction DR1 may be in contact with each of the first contact isolation layer 141 and the second contact isolation layer 142. For example, both sidewalls of the second source/drain contact CA2 in the second horizontal direction DR2 may be in contact with the field insulating layer 105. For example, at least a portion of both sidewalls of the second source/drain contact CA2 in the second horizontal direction DR2 may be in contact with the liner layer 150. For example, at least a portion of the second source/drain contact CA2 may extend into the inside of the source/drain region SD. The second source/drain contact CA2 may be electrically connected to the source/drain region SD.

The second source/drain contact CA2 may include a first portion CA2_1 and a second portion CA2_2 disposed on the upper surface CA2_1a of the first portion CA2_1. For example, the first portion (CA2_1) of the second source/drain contact (CA2) may be defined as the portion disposed between the upper surface of the lower interlayer insulating layer (100) and the lower surface of the liner layer (150). For example, the lower surface of the first portion CA2_1 of the second source/drain contact CA2 may be in contact with the upper surface of the lower interlayer insulating layer 100. At least a portion of the upper surface (CA2_1a) of the first portion (CA2_1) of the second source/drain contact (CA2) may be in contact with the lower surface of the liner layer (150).

For example, both sidewalls of the first portion CA2_1 of the second source/drain contact CA2 in the first horizontal direction DR1 may be in contact with each of the first and second contact isolation layers 141, 142. For example, the vertex P1 of the first contact isolation layer 141 may be disposed on one sidewall of the first portion CA2_1 of the second source/drain contact CA2 in the first horizontal direction DR1. For example, one sidewall of the first portion CA2_1 of the second source/drain contact CA2 in the first horizontal direction DR1 may be in contact with the first sidewall 141s1 of the first contact isolation layer 141. Further, one sidewall of the first portion CA2_1 of the second source/drain contact CA2 in the first horizontal direction DR1 may be in contact with at least a portion of the second sidewall 141s2 of the first contact isolation layer 141.

For example, both sidewalls of the first portion CA2_1 of the second source/drain contact CA2 in the first horizontal direction DR1 may be in contact with the field insulating layer 105. For example, at least a portion of both sidewalls of the first portion CA2_1 of the second source/drain contact CA2 in the first horizontal direction DR1 may be in contact with the liner layer 150. For example, at least a portion of the liner layer 150 may be disposed between both sidewalls of the first portion CA2_1 of the second source/drain contact CA2 in the first horizontal direction DR1 and the field insulating layer 105.

For example, the second portion CA2_2 of the second source/drain contact CA2 may be defined as the portion extending into the inside of the source/drain region SD by penetrating or extending into each of the liner layer 150 and the active pattern 101 in the vertical direction DR3. For example, the second portion CA2_2 of the second source/drain contact CA2 may be spaced apart from each of the first and second contact isolation layers 141, 142 in the first horizontal direction DR1. For example, the lower surface of the second portion CA2_2 of the second source/drain contact CA2 may be in contact with the upper surface CA2_1a of the first portion CA2_1 of the second source/drain contact CA2. In other words, the liner layer 150 and the active pattern 101 are not disposed between the upper surface CA2_la of the first portion CA2_1 of the second source/drain contact CA2 and the lower surface of the second portion CA2_2 of the second source/drain contact CA2.

For example, the width of the lower surface of the second portion CA2_2 of the second source/drain contact CA2 in the first horizontal direction DR1 may be smaller than the width of the upper surface of the first portion CA2_1 of the second source/drain contact CA2 in the first horizontal direction DR1. For example, the width of the lower surface of the second portion CA2_2 of the second source/drain contact CA2 in the second horizontal direction DR2 may be smaller than the width of the upper surface of the first portion CA2_1 of the second source/drain contact CA2 in the second horizontal direction DR2. For example, both sidewalls of the second portion CA2_2 of the second source/drain contact CA2 in the first horizontal direction DR1 may be in contact with each of the liner layer 150 and the active pattern 101. For example, both sidewalls of the second portion CA2_2 of the second source/drain contact CA2 in the second horizontal direction DR2 may be in contact with each of the liner layer 150 and the active pattern 101. However, the present disclosure is not limited thereto. In some embodiments, an insulating layer including an insulating material may be disposed between the second portion CA2_2 of the second source/drain contact CA2 and the active pattern 101. For example, the second source/drain contact CA2 may be formed as a single layer. However, the present disclosure is not limited thereto. In some embodiments, the second source/drain contact CA2 may be formed of multiple layers. For example, the second source/drain contact CA2 may include a conductive material.

A silicide layer SL may be disposed between the second source/drain contact CA2 and the source/drain region SD. For example, the silicide layer SL may be disposed between the second portion CA2_2 of the second source/drain contact CA2 and the source/drain region SD. The silicide layer SL may be disposed along the interface between the second portion CA2_2 of the second source/drain contact CA2 and the source/drain region SD. For example, the lower surface of the silicide layer SL may be in contact with the active pattern 101. For example, the silicide layer SL may include a metal silicide material.

The first etch stop layer 160 may be disposed on the sidewalls of each of the first and second gate spacers 111, 112 in the first horizontal direction DR1. The first etch stop layer 160 may be disposed on the upper surface of the field insulating layer 105. The first etch stop layer 160 may be disposed on the upper surface of the source/drain region SD. The first etch stop layer 160 may be disposed on the sidewalls of the source/drain region SD in the second horizontal direction DR2. For example, the first etch stop layer 160 may be formed conformally on the sidewalls of the source/drain region SD. The first etch stop layer 160 may include, for example, at least one of aluminum oxide, aluminum nitride, hafnium oxide, zirconium oxide, silicon oxide, silicon nitride, silicon oxynitride, and/or low-k materials.

The first capping pattern 131 may extend on each of the first gate spacer 111, the first gate insulating layer 121, and the first gate electrode G1 in the second horizontal direction DR2. The second capping pattern 132 may extend on each of the second gate spacer 112, the second gate insulating layer 122, and the second gate electrode G2 in the second horizontal direction

DR2. For example, the lower surface of each of the first and second capping patterns 131, 132 may be in contact with the first etch stop layer 160. However, the present disclosure is not limited thereto. In some embodiments, the sidewalls of each of the first and second capping patterns 131, 132 may be in contact with the first etch stop layer 160. Each of the first and second capping patterns 131, 132 may include, for example, at least one of silicon nitride (SiN), silicon oxynitride (SiON), silicon oxide (SiO₂), silicon carbonitride (SiCN), silicon oxycarbonitride (SiOCN), and/or combinations thereof. However, the present disclosure is not limited thereto.

The first upper interlayer insulating layer 170 may be disposed on the first etch stop layer 160. The first upper interlayer insulating layer 170 may be disposed on the sidewalls of each of the first and second capping patterns 131, 132. The first upper interlayer insulating layer 170 may cover or overlap the source/drain region SD on the field insulating layer 105. For example, the upper surface of the first upper interlayer insulating layer 170 may be formed on the same plane as the upper surface of each of the first and second capping patterns 131, 132. The first upper interlayer insulating layer 170 may include, for example, at least one of silicon oxide, silicon nitride, silicon oxynitride, and low-k materials.

The first gate contact CB1 may be connected to the first gate electrode G1 by penetrating or extending into the first capping pattern 131 in the vertical direction DR3. The second gate contact CB2 may be connected to the second gate electrode G2 by penetrating or extending into the second capping pattern 132 in the vertical direction DR3. In FIGS. 2 and 3, the first gate contact CB1 is shown disposed on the first plurality of nanosheets NW1, and the second gate contact CB2 is shown disposed on the second plurality of nanosheets NW2, but the present disclosure is not limited thereto. In some embodiments, each of the first and second gate contacts CB1, CB2 may be disposed on the field insulating layer 105.

In FIGS. 2 and 3, each of the first and second gate contacts CB1, CB2 is shown as being formed as a single layer, but the present disclosure is not limited thereto. In some embodiments, each of the first and second gate contacts CB1, CB2 may be formed as multiple layers. For example, the upper surface of each of the first and second gate contacts CB1, CB2 may be formed on the same plane as the upper surface of the first upper interlayer insulating layer 170, but the present disclosure is not limited thereto. Each of the first and second gate contacts CB1, CB2 may include a conductive material.

The second etch stop layer 180 may be disposed on the upper surface of the first upper interlayer insulating layer 170 and on the upper surfaces of the first and second gate contacts CB1, CB2, respectively. In FIGS. 2 to 4, the second etch stop layer 180 is shown as being formed as a single layer, but the present disclosure is not limited thereto. In some embodiments, the second etch stop layer 180 may be formed as multiple layers. The second etch stop layer 180 may include, for example, at least one of aluminum oxide, aluminum nitride, hafnium oxide, zirconium oxide, silicon oxide, silicon nitride, silicon oxynitride, and/or low-k materials. The second upper interlayer insulating layer 185 may be disposed on the second etch stop layer 180. The second upper interlayer insulating layer 185 may include, for example, at least one of silicon oxide, silicon nitride, silicon oxynitride, and/or low-k materials.

The first via V1 may be connected to the second source/drain contact CA2 by penetrating or extending into the lower interlayer insulating layer 100 in the vertical direction DR3. The second via V2 may be connected to the first gate contact CB1 by penetrating or extending into the second upper interlayer insulating layer 185 and the second etch stop layer 180 in the vertical direction DR3. The third via V3 may be connected to the second gate contact CB2 by penetrating or extending into the second upper interlayer insulating layer 185 and the second etch stop layer 180 in the vertical direction DR3. In FIGS. 2 to 4, each of the first to third vias V1, V2, V3 is shown as being formed as a single layer, but the present disclosure is not limited thereto. In some embodiments, each of the first to third vias V1, V2, V3 may be formed as multiple layers. Each of the first to third vias V1, V2, V3 may include a conductive material.

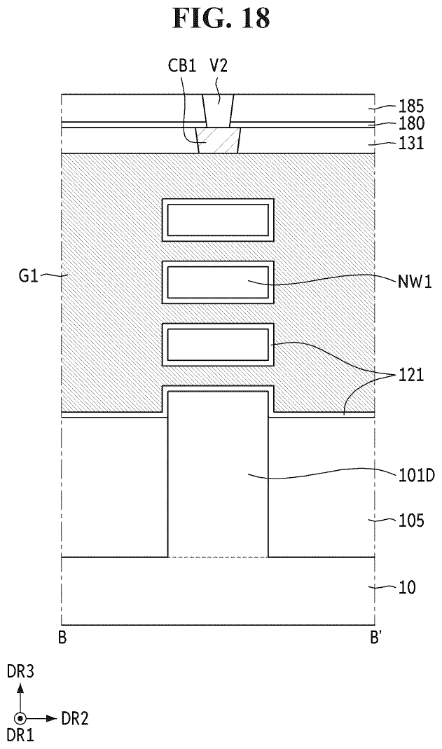

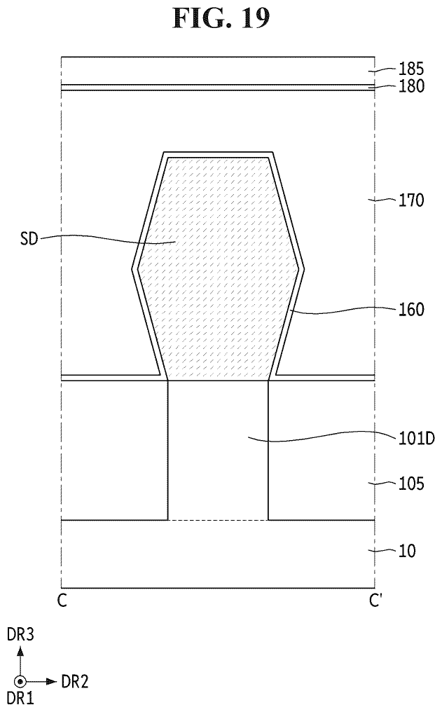

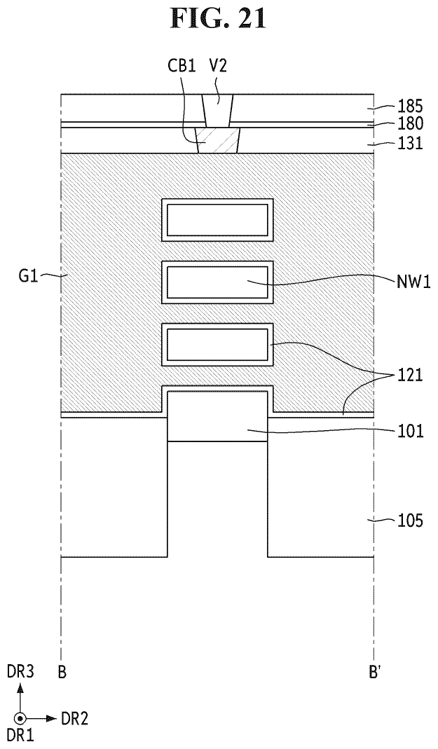

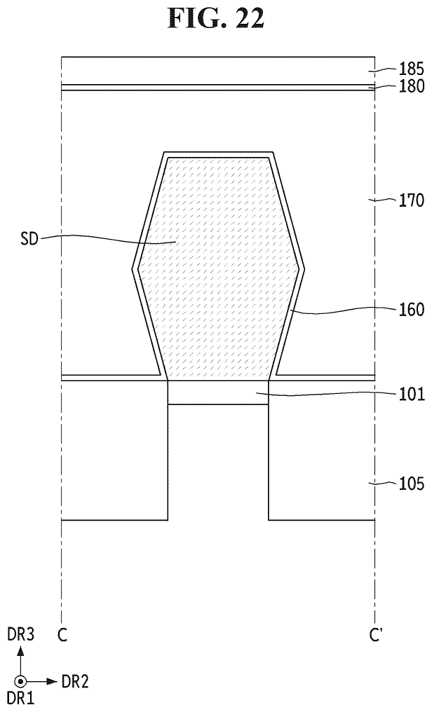

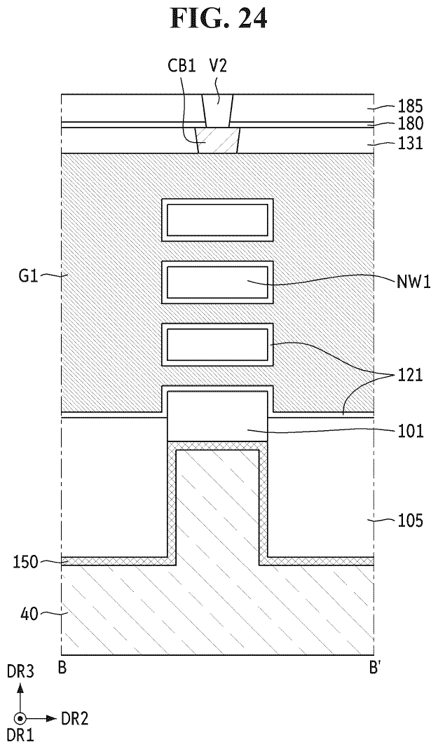

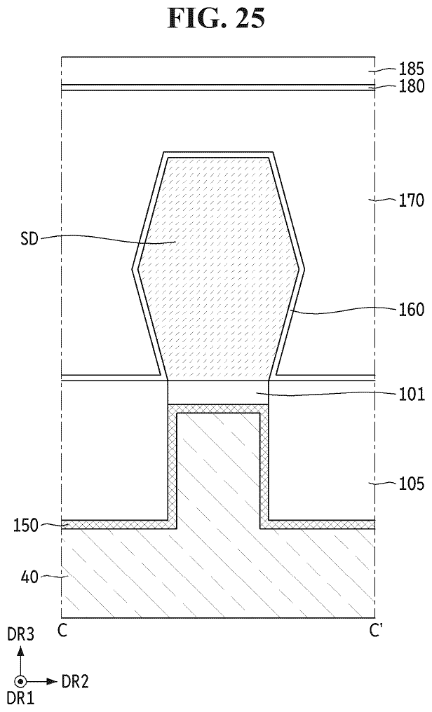

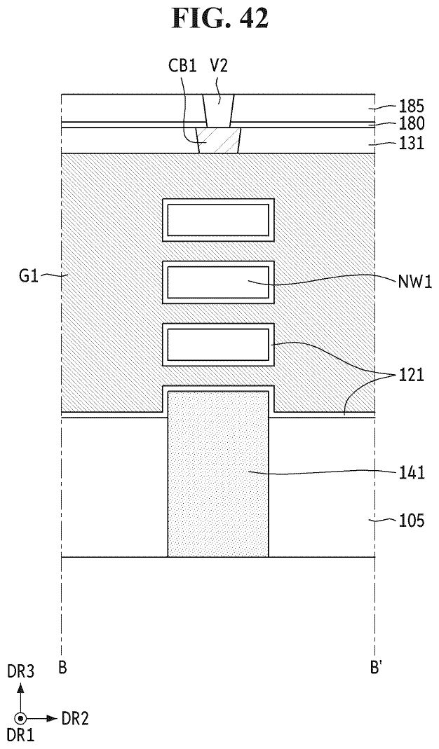

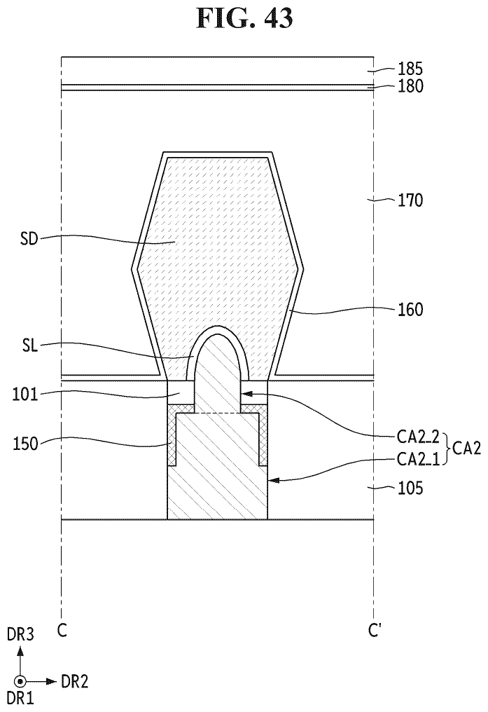

Hereinafter, with reference to FIGS. 2 to 43, a method of fabricating a semiconductor device according to some embodiments of the present disclosure will be described.

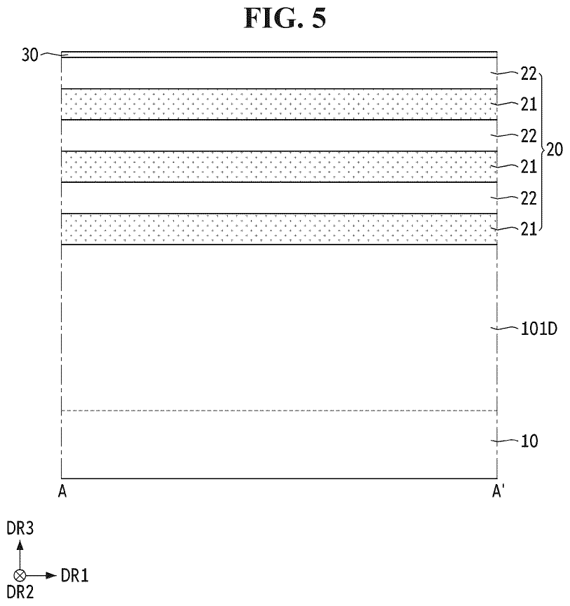

FIGS. 5 to 43 are intermediate stage diagrams for explaining the method of fabricating the semiconductor device according to some embodiments of the present disclosure.

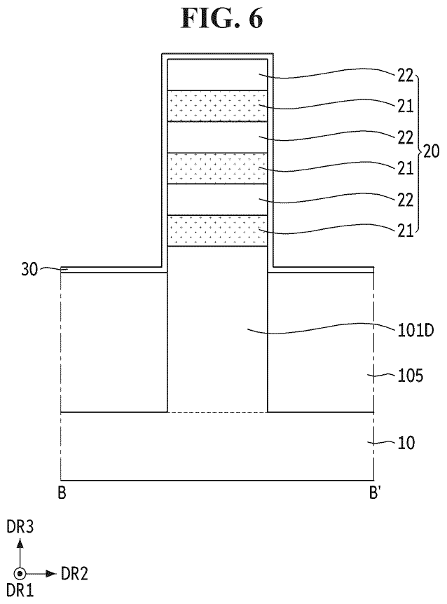

Referring to FIGS. 5 and 6, a substrate 10 may be provided. The substrate 10 may be a silicon substrate or SOI (silicon-on-insulator). In some embodiments, the substrate 10 may include silicon germanium, SGOI (silicon germanium on insulator), indium antimonide, lead telluride compounds, indium arsenide, indium phosphide, gallium arsenide, or gallium antimonide, but the present disclosure is not limited thereto.

Subsequently, a laminated structure 20 may be formed on the substrate 10. The laminated structure 20 may include a first semiconductor layer 21 and a second semiconductor layer 22 alternately stacked on the substrate 10. For example, the first semiconductor layer 21 may be formed on the lowermost part of the laminated structure 20, and the second semiconductor layer 22 may be formed on the uppermost part of the laminated structure 20. However, the present disclosure is not limited thereto. In some embodiments, the first semiconductor layer 21 may also be formed on the uppermost part of the laminated structure 20. The first semiconductor layer 21 may include, for example, silicon germanium (SiGe). The second semiconductor layer 22 may include, for example, silicon (Si).

Subsequently, a portion of the laminated structure 20 may be etched. While the laminated structure 20 is being etched, a portion of the substrate 10 may also be etched. Through this etching process, a dummy active pattern 101D may be defined on the lower part of the laminated structure 20 on the upper surface of the substrate 10. The dummy active pattern 101D may protrude or extend from the upper surface of the substrate 10 in the vertical direction DR3. The dummy active pattern 101D may extend in the first horizontal direction DR1. For example, the dummy active pattern 101D may include silicon (Si).

Subsequently, the field insulating layer 105 may be formed on the upper surface of the substrate 10. The field insulating layer 105 may surround at least a portion of the sidewalls of the dummy active pattern 101D. The field insulating layer 105 may be in contact with the dummy active pattern 101D. For example, the upper surface of the field insulating layer 105 may be formed to be lower than the upper surface of the dummy active pattern 101D. Subsequently, a pad oxide layer 30 may be formed to cover or overlap the upper surface of the field insulating layer 105, the exposed sidewalls of the dummy active pattern 101D, and the sidewalls and upper surface of the stacked structure 20. For example, the pad oxide layer 30 may be formed conformally on the field insulating layer 105. The pad oxide layer 30 may include, for example, silicon oxide (SiO₂).

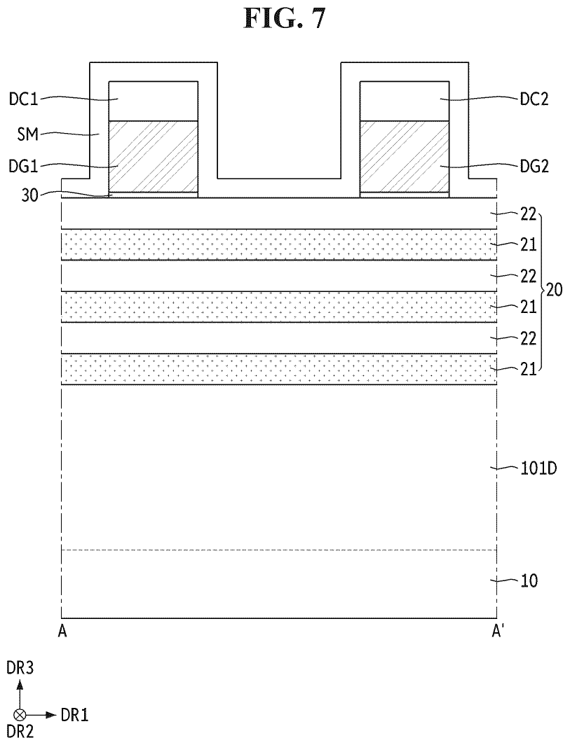

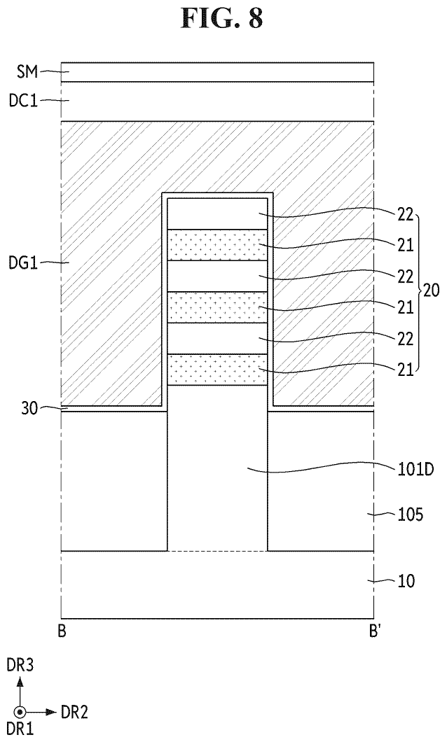

Referring to FIGS. 7 and 8, first and second dummy gates DG1, DG2 and first and second dummy capping patterns DC1, DC2 extending in the second horizontal direction DR2 may be formed on the pad oxide layer 30 on the laminated structure 20 and field insulating layer 105. For example, the second dummy gate DG2 may be spaced apart from the first dummy gate DG1 in the first horizontal direction DR1. The first dummy capping pattern DC1 may be disposed on the first dummy gate DG1. The second dummy capping pattern DC2 may be disposed on the second dummy gate DG2. While the first and second dummy gates DG1, DG2 and the first and second dummy capping patterns DC1, DC2 are being formed, the remaining pad oxide layer 30 on the substrate 10 may be removed except for the portions that overlap with each of the first and second dummy gates DG1, DG2 in the vertical direction DR3.

Subsequently, the spacer material layer SM may be formed to cover or overlap the sidewalls of each of the first and second dummy gates DG1, DG2, the sidewalls and upper surfaces of the first and second dummy capping patterns DC1, DC2, the sidewalls and upper surface of the exposed laminated structure 20, and the upper surface of the field insulating layer 105. For example, the spacer material layer SM may be formed conformally on the first and second dummy gates DG1, DG2, the sidewalls and upper surfaces of the first and second dummy capping patterns DC1, DC2, the sidewalls and upper surface of the exposed laminated structure 20, and the upper surface of the field insulating layer 105. The spacer material layer SM may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and/or combinations thereof.

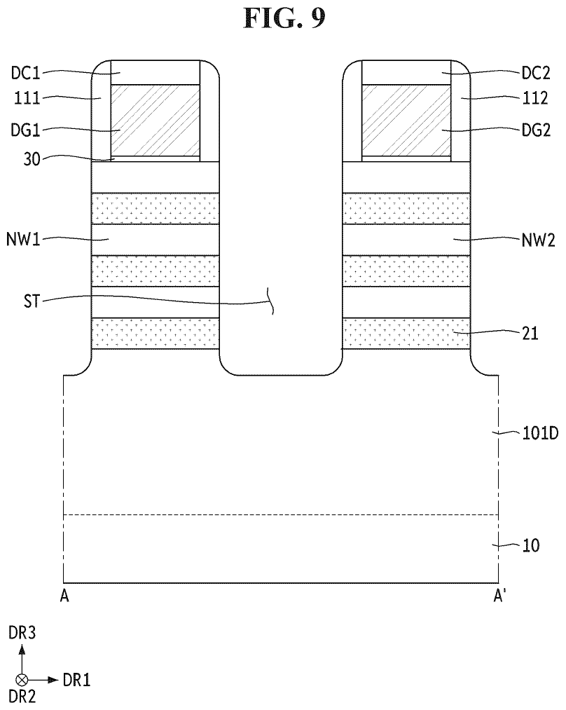

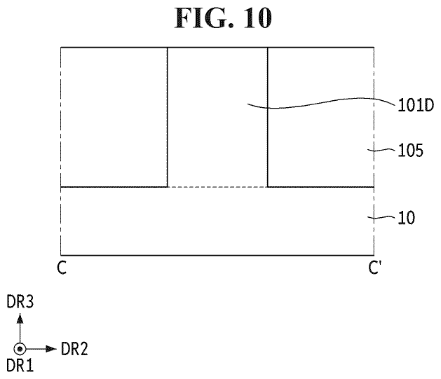

Referring to FIGS. 9 and 10, using the first and second dummy gates DG1, DG2 and the first and second dummy capping patterns DC1, DC2 as masks, the laminated structure 20 (see FIG. 7) may be etched to form the source/drain trench ST. The source/drain trench ST may be formed between the first dummy gate DG1 and the second dummy gate DG2 on the dummy active pattern 101D. For example, the source/drain trench ST may extend into the inside of the dummy active pattern 101D. For example, while the source/drain trench ST is being formed, the spacer material layer SM (see FIG. 7) formed on the upper surface of each of the first and second dummy capping patterns DC1, DC2, and a portion of each of the first and second dummy capping patterns DC1, DC2 may be etched.

The spacer material layers SM (see FIG. 7) remaining on the sidewalls of each of the first and second dummy capping patterns DC1, DC2 and the first and second dummy gates DG1, DG2 may be defined as the first and second gate spacers 111, 112. For example, after the source/drain trench ST is formed, the second semiconductor layer 22 (see FIG. 7) remaining on the lower part of the first dummy gate DG1 may be defined as the first plurality of nanosheets NW1. After the source/drain trench ST is formed, the second semiconductor layer 22 (see FIG. 7) remaining on the lower part of the second dummy gate DG2 may be defined as the second plurality of nanosheets NW2.

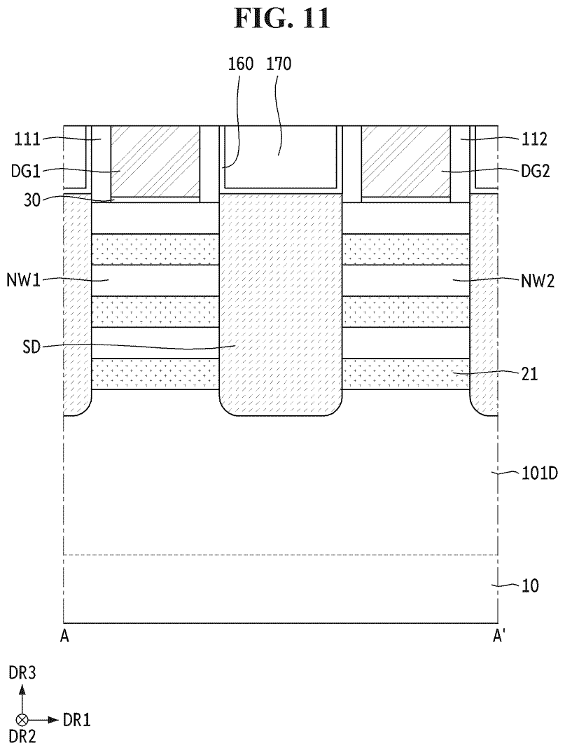

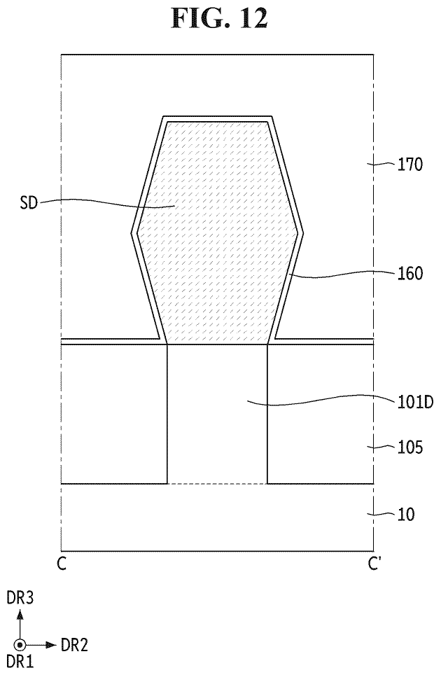

Referring to FIGS. 11 and 12, the source/drain region SD may be formed inside the source/drain trench ST. For example, the lower surface of the source/drain region SD may be in contact with the dummy active pattern 101D. Subsequently, the first etch stop layer 160 may be formed on the exposed upper surface of the field insulating layer 105, the exposed sidewalls of each of the first and second gate spacers 111, 112, the exposed upper surface of each of the first and second dummy capping patterns DC1, DC2 (see FIG. 9), and the exposed surface of the source/drain region SD. Subsequently, the first upper interlayer insulating layer 170 may be formed on the first etch stop layer 160. Subsequently, by performing a planarization process, the upper surfaces of each of the first and second dummy gates DG1, DG2 may be exposed.

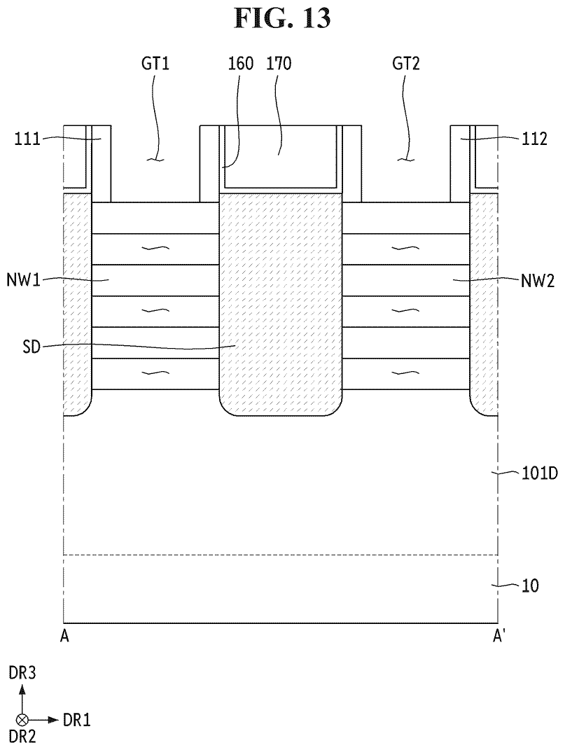

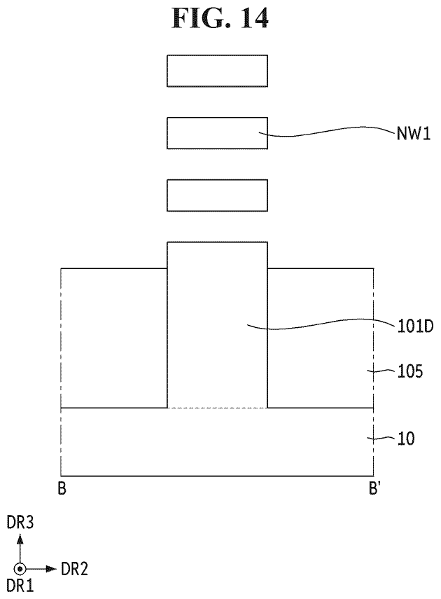

Referring to FIGS. 13 and 14, the first and second dummy gates DG1, DG2 (see FIG. 11), the pad oxide layer 30 (see FIG. 11), and the first semiconductor layer 21 (see FIG. 11) may be etched, respectively. The portions in which the first dummy gate DG1 (see FIG. 11), the pad oxide layer 30 (see FIG. 11), and the first semiconductor layer 21 (see FIG. 11) are etched may be defined as the first gate trench GT1. Further, the portions in which the second dummy gate DG2 (see FIG. 11), the pad oxide layer 30 (see FIG. 11), and the first semiconductor layer 21 (see FIG. 11) are etched may be defined as the second gate trench GT2.

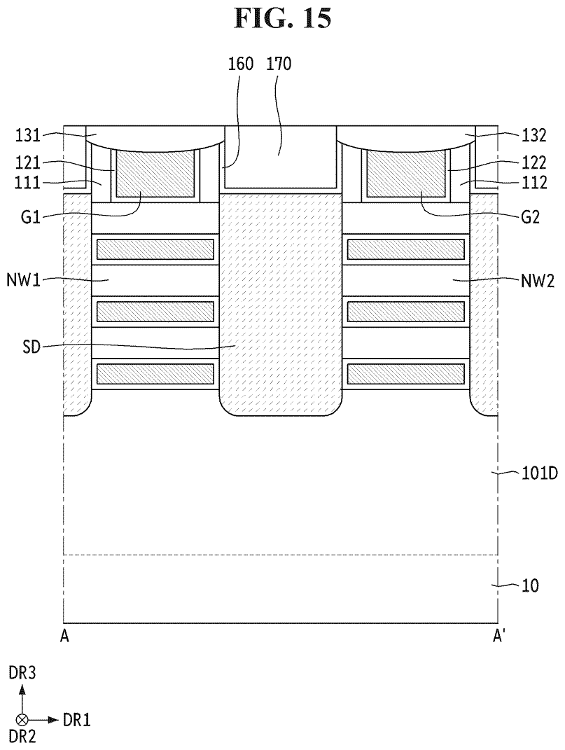

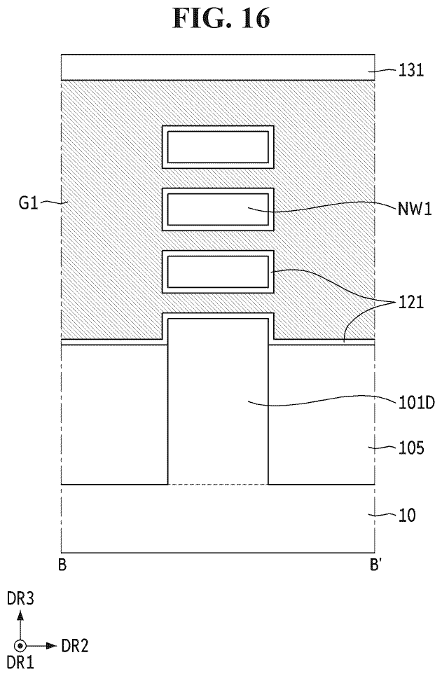

Referring to FIGS. 15 and 16, the first gate insulating layer 121, the first gate electrode G1, and the first capping pattern 131 may each be formed sequentially inside the first gate trench GT1 (see FIG. 13). Further, the second gate insulating layer 122, the second gate electrode G2, and the second capping pattern 132 may each be formed sequentially inside the second gate trench GT2 (see FIG. 13). For example, the first gate electrode G1 may surround the first plurality of nanosheets NW1. The second gate electrode G2 may surround at least a portion of the second plurality of nanosheets NW2.

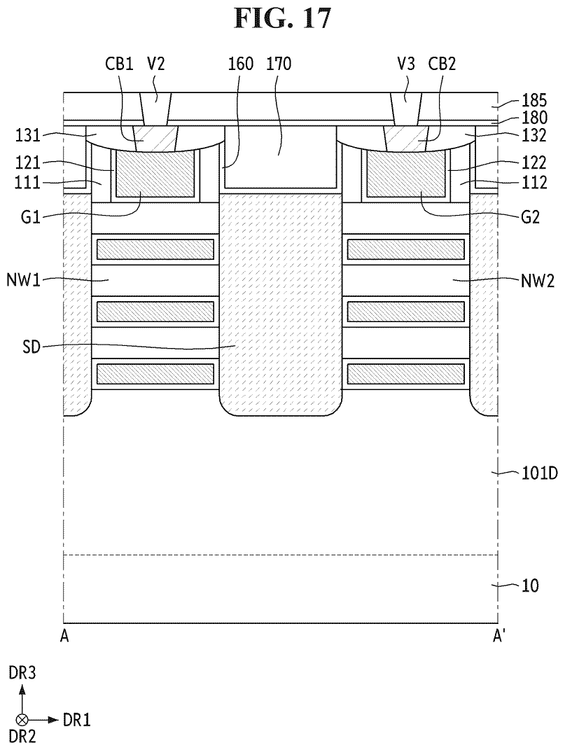

Referring to FIGS. 17 to 19, the first gate contact CB1 connected to the first gate electrode G1 may be formed by penetrating or extending into the first capping pattern 131 in the vertical direction DR3. Additionally, the second gate contact CB2 connected to the second gate electrode G2 may be formed by penetrating or extending into the second capping pattern 132 in the vertical direction DR3. Subsequently, the second etch stop layer 180 and the second upper interlayer insulating layer 185 may be formed sequentially on the upper surfaces of the first upper interlayer insulating layer 170, and the first and second gate contacts CB1, CB2, respectively. Subsequently, the first via V1 connected to the first gate contact CB1 may be formed by penetrating or extending into the second etch stop layer 180 and the second upper interlayer insulating layer 185 in the vertical direction DR3. Further, the second via V2 connected to the second gate contact CB2 may be formed by penetrating or extending into the second etch stop layer 180 and the second upper interlayer insulating layer 185 in the vertical direction DR3.

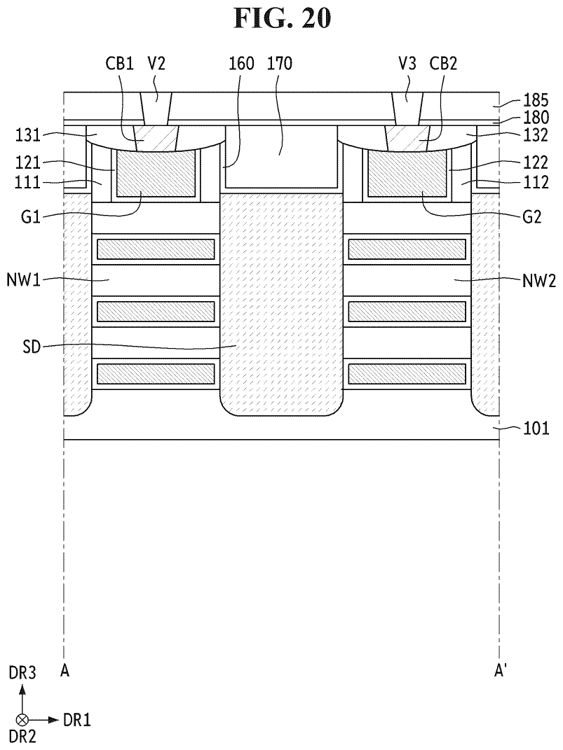

Referring to FIGS. 20 to 22, the substrate 10 (see FIGS. 17 to 19) may be etched. Further, a portion of the dummy active pattern 101D (see FIGS. 17 to 19) may be etched. After a portion of the dummy active pattern 101D (see FIGS. 17 to 19) is etched, the remaining dummy active pattern 101D (FIGS. 17 to 19) may be defined as the active pattern 101. For example, the lower surface of the active pattern 101 may be formed to be higher than the lower surface of the field insulating layer 105.

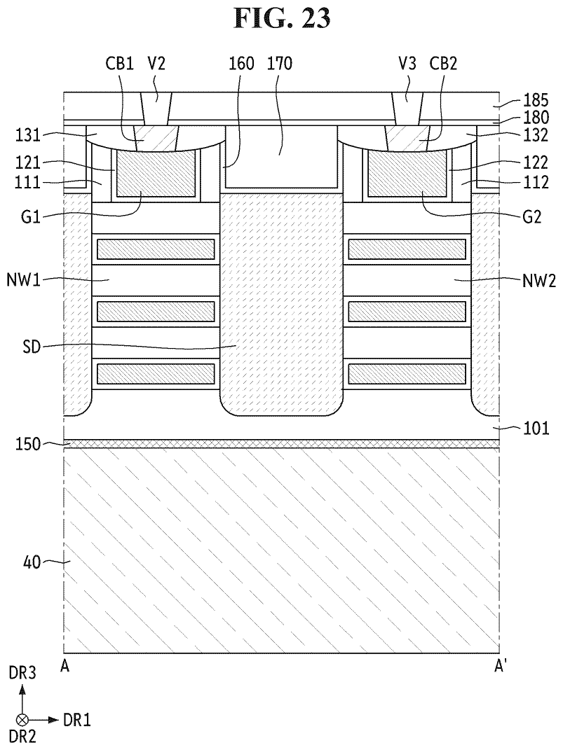

Referring to FIGS. 23 to 25, the liner layer 150 may be formed on the lower surface of the active pattern 101, the lower surface and the exposed sidewalls of the field insulating layer 105. For example, the liner layer 150 may be formed conformally on the lower surface of the active pattern 101 and the lower surface and the exposed sidewalls of the field insulating layer 105. Subsequently, a first sacrificial layer 40 may be formed on the lower surface of the liner layer 150. For example, the first sacrificial layer 40 may include a SOH (Spin-On Hardmask).

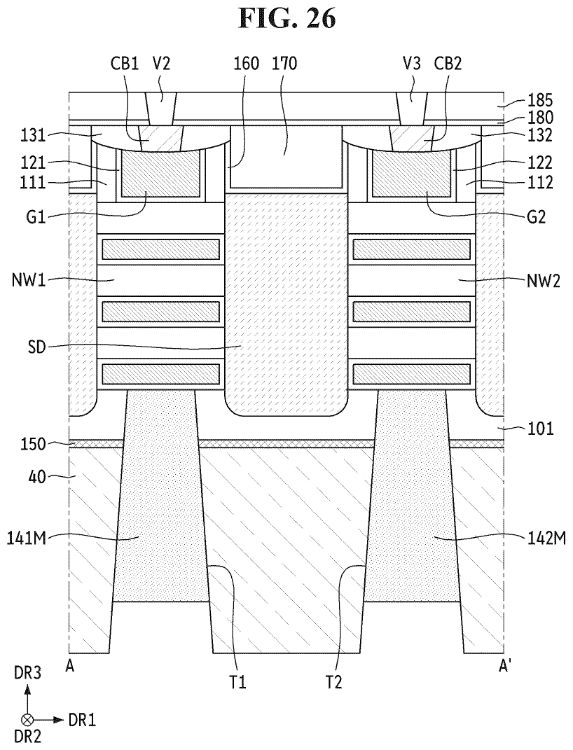

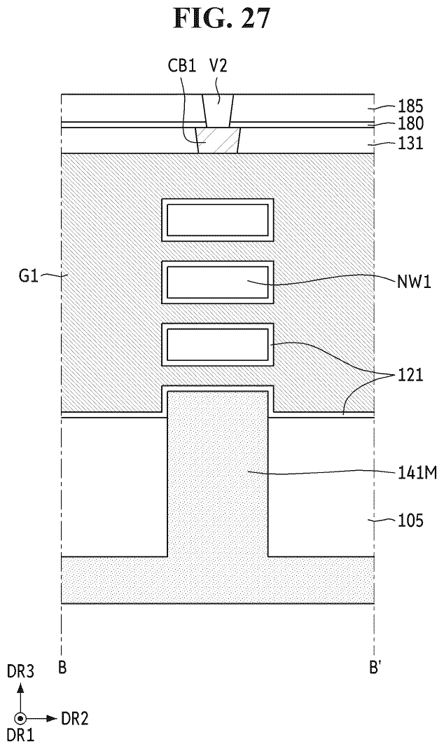

Referring to FIGS. 26 to 27, a first isolation trench TI may be formed on the lower part of the first gate electrode G1. For example, the first isolation trench Tl may extend in the second horizontal direction DR2. For example, the first isolation trench TI may extend through the first sacrificial layer 40, the liner layer 150, and the active pattern 101 to the upper surface of the active pattern 101 in the vertical direction DR3. For example, through the first isolation trench T1, the first gate insulating layer 121, the sidewall of the active pattern 101 in the first horizontal direction DR1, the sidewall of the liner layer 150 in the first horizontal direction DR1, the sidewall and the lower surface of the field insulating layer 105 in the second horizontal direction DR2 may each be exposed.

Additionally, the second isolation trench T2 may be formed on the lower part of the second gate electrode G2. For example, the second isolation trench T2 may extend in the second horizontal direction DR2. For example, the second isolation trench T2 may extend to the uppermost surface of the active pattern 101 by penetrating or extending into the first sacrificial layer 40, the liner layer 150, and the active pattern 101 in the vertical direction DR3. For example, through the second isolation trench T2, the second gate insulating layer 122, the sidewall of the active pattern 101 in the first horizontal direction DR1, the side wall of the liner layer 150 in the first horizontal direction DR1, the sidewall and the lower surface of the field insulating layer 105 in the second horizontal direction DR2 may each be exposed.

Subsequently, the first isolation material layer 141M may be formed inside the first isolation trench Tl and the second isolation material layer 142M may be formed inside the second isolation trench T2. Subsequently, an etch-back etching process may be performed, wherein a portion of each of the first isolation material layer 141M and the second isolation material layer 142M may be etched. For example, after the etch-back etching process is performed, each of the remaining first isolation material layer 141M and the second isolation material layer 142M may cover or overlap the lower surface of the field insulating layer 105. For example, each of the first isolation material layer 141M and the second isolation material layer 142M may include silicon oxide (SiO₂), titanium oxide (TiO₂), or silicon nitride (SiN).

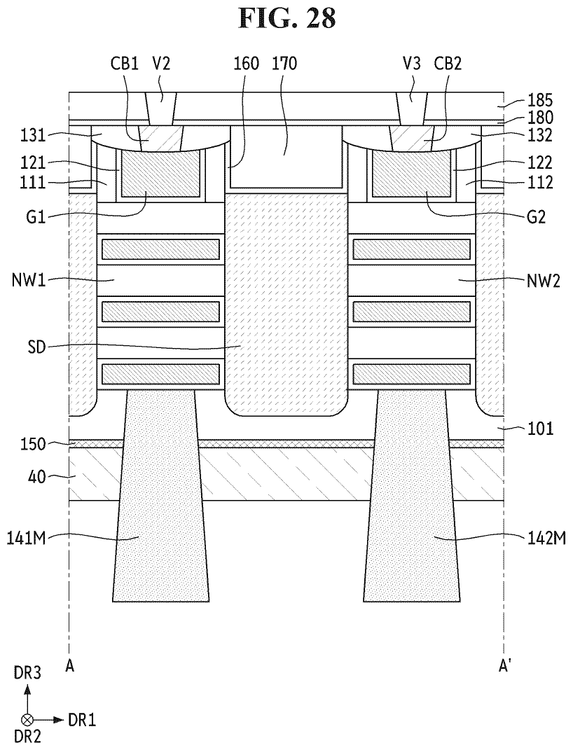

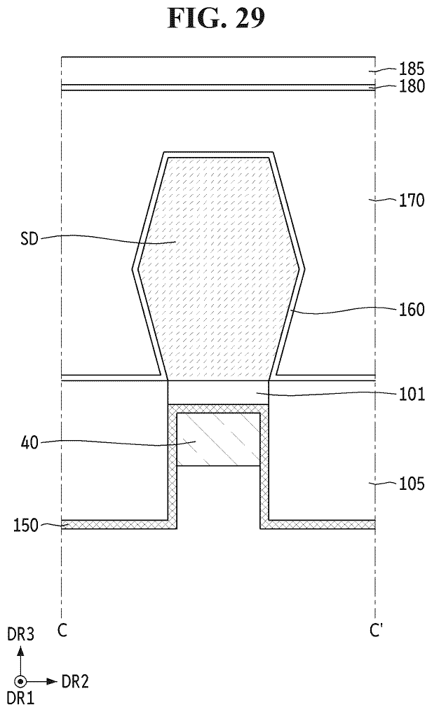

Referring to FIGS. 28 and 29, a portion of the first sacrificial layer 40 may be etched. After a portion of the first sacrificial layer 40 is etched, the lower surface of the remaining first sacrificial layer 40 may be formed to be higher than the lower surface of the field insulating layer 105. For example, after a portion of the first sacrificial layer 40 is etched, a portion of both sidewalls in the first horizontal direction DR1 of each of the first isolation material layer 141M and the second isolation material layer 142M may be exposed. For example, after a portion of the first sacrificial layer 40 is etched, the liner layer 150 formed on the lower surface and part of the sidewalls in the second horizontal direction DR2 of the field insulating layer may be exposed.

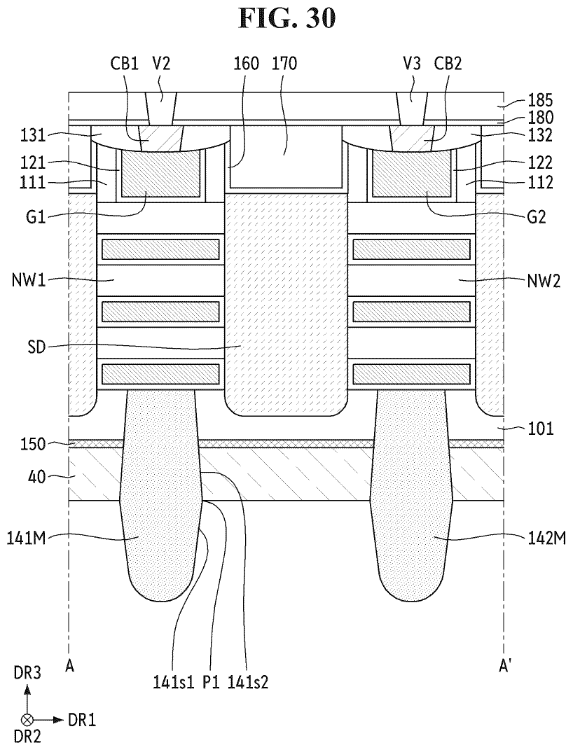

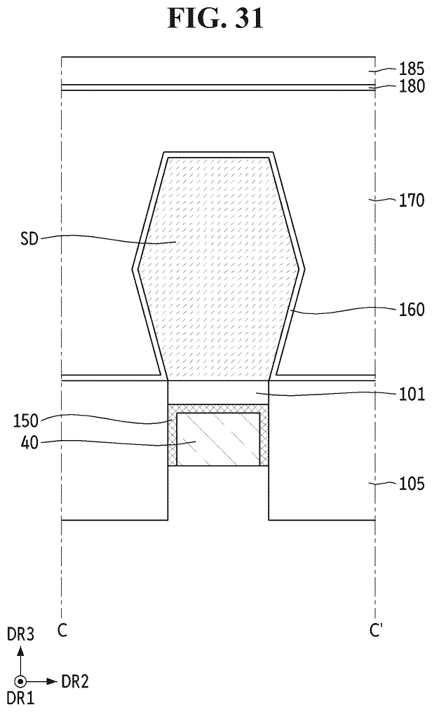

Referring to FIGS. 30 and 31, a portion of both sidewalls of each of the first isolation material layer 141M and the second isolation material layer 142M in the first horizontal direction DR1 exposed on the lower surface of the first sacrificial layer 40 may be etched. While a portion of both sidewalls of each of the first isolation material layer 141M and the second isolation material layer 142M in the first horizontal direction DR1 are etched, the liner layer 150 exposed on the lower surface of the first sacrificial layer 40 may be etched. Consequently, a portion of the sidewalls and the lower surface of the field insulating layer 105 in the second horizontal direction DR2 may be exposed.

For example, after a portion of both sidewalls of each of the first isolation material layer 141M and the second isolation material layer 142M in the first horizontal direction DR1 are etched, the sidewall of the first isolation material layer 141M in the first horizontal direction DR1 exposed on the lower surface of the first sacrificial layer 40 may be defined as the first sidewall 141s1. Further, the sidewall of the first isolation material layer 141M in the first horizontal direction DR1 that is in contact with each of the first sacrificial layer 40, the liner layer 150, and the active pattern 101 may be defined as the second sidewall 141s2. Additionally, the point at which the first sidewall 141s1 of the first isolation material layer 141M and the second sidewall 141s2 of the first isolation material layer 141M are connected may be defined as the vertex P1. For example, the vertex P1 may be formed at the same height as the lower surface of the first sacrificial layer 40. For example, the slope profile of the first sidewall 141s1 of the first isolation material layer 141M and the slope profile of the second sidewall 141s2 of the first isolation material layer 141M may be formed differently based on the vertex P1.

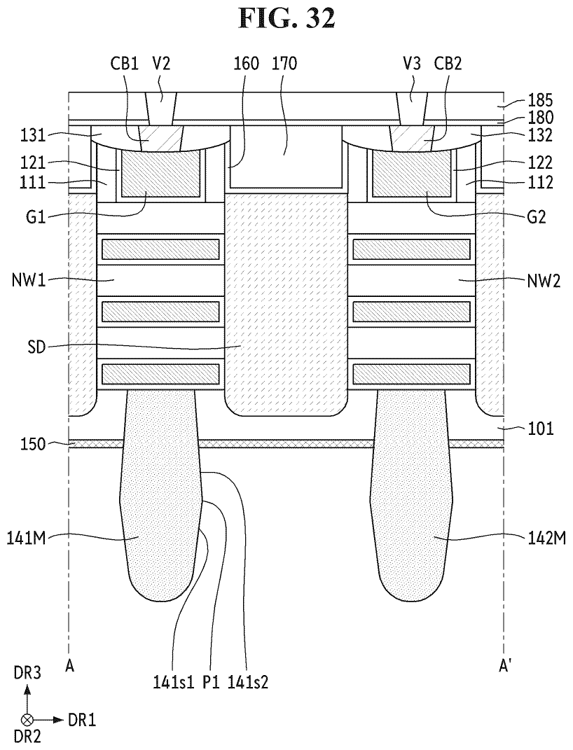

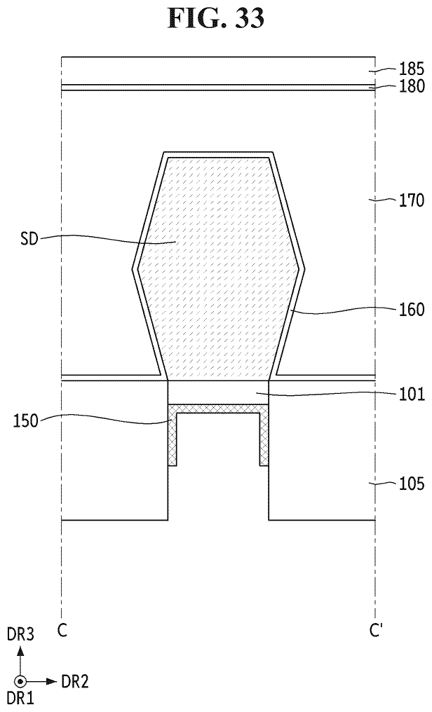

Referring to FIGS. 32 and 33, the first sacrificial layer 40 (see FIGS. 30 and 31) may be etched. As a result, a portion of the second sidewall 141s2 of the first isolation material layer 141M may be exposed. Additionally, the liner layer 150 may be exposed.

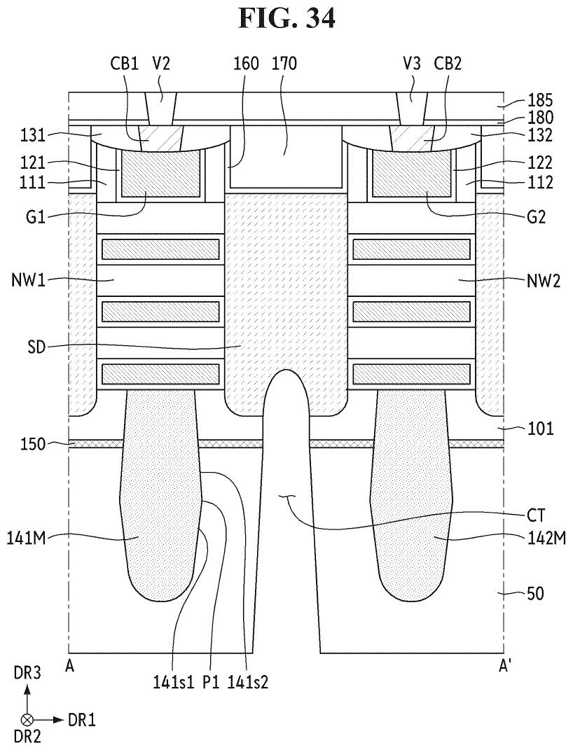

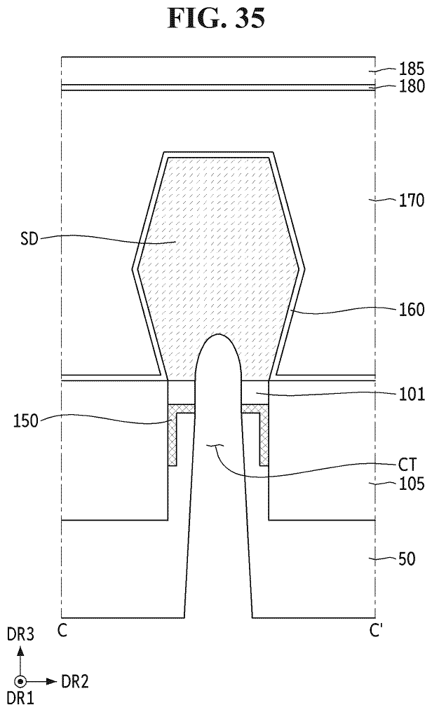

Referring to FIGS. 34 and 35, the second sacrificial layer 50 may be formed on the lower surface of the liner layer 150 and the lower surface of the field insulating layer 105. For example, the second sacrificial layer 50 may cover or overlap each of the exposed first and second isolation material layers 141M, 142M. For example, the second sacrificial layer 50 may include a SOH (Spin-On Hardmask). Subsequently, the contact trench CT extending between the first isolation material layer 141M and the second isolation material layer 142M in the vertical direction DR3 may be formed. For example, the contact trench CT may extend inside the source/drain region SD by penetrating or extending into each of the second sacrificial layer 50, the liner layer 150, and the active pattern 101. In other words, the source/drain region SD may be exposed through the contact trench CT.

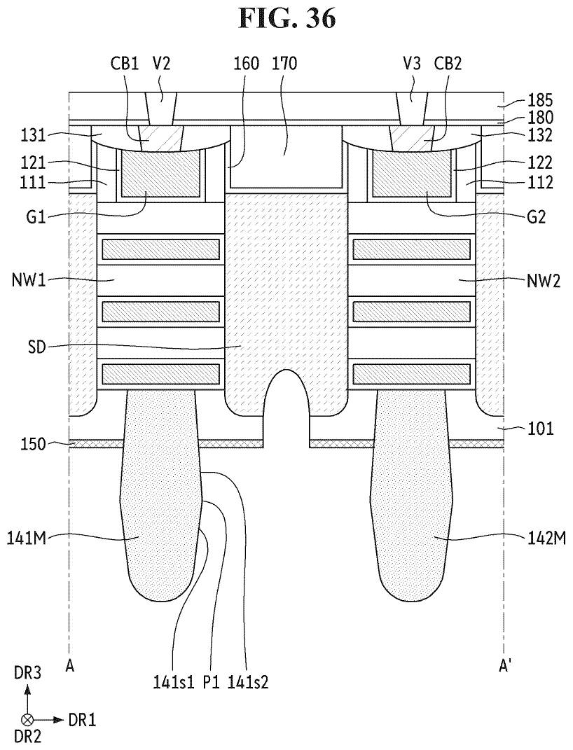

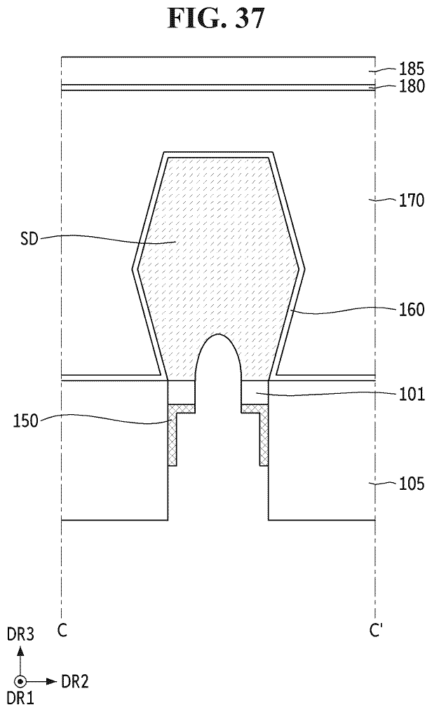

Referring to FIGS. 36 and 37, the second sacrificial layer 50 (see FIGS. 34 and 35) may be etched.

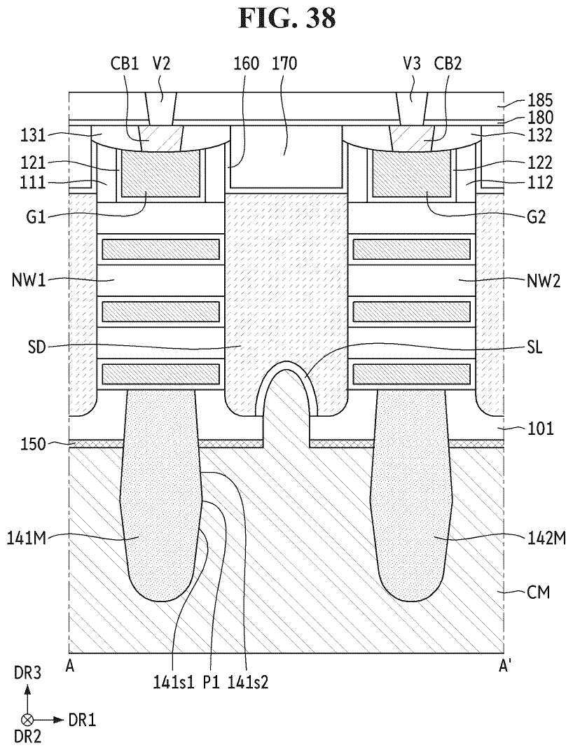

Referring to FIGS. 38 to 40, the contact material layer CM may be formed on the lower surface of the liner layer 150. For example, the contact material layer CM may fill or be in the etched portion of the source/drain region SD. Further, the contact material layer CM may be in contact with the sidewalls of each of the exposed active pattern 101 and the liner layer 150 in the first horizontal direction DR1 in the lower part of the source/drain region SD. Further, the contact material layer CM may cover or overlap each of the first and second isolation material layers 141M, 142M exposed on the lower surface of the liner layer 150. Additionally, the contact material layer CM may cover or overlap the lower surface of the field insulating layer 105. For example, the contact material layer CM may include a conductive material.

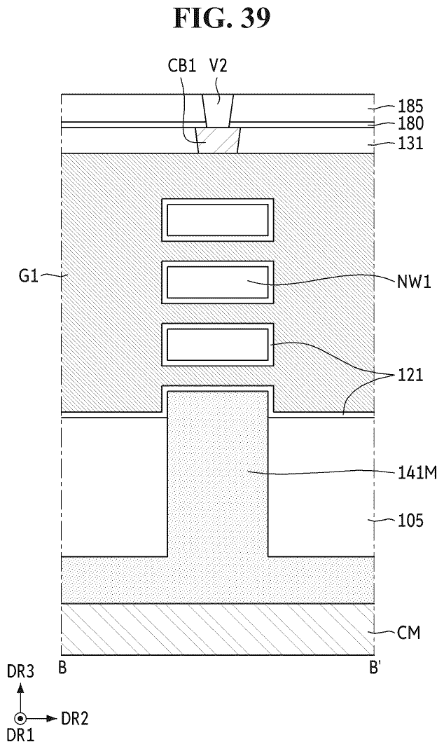

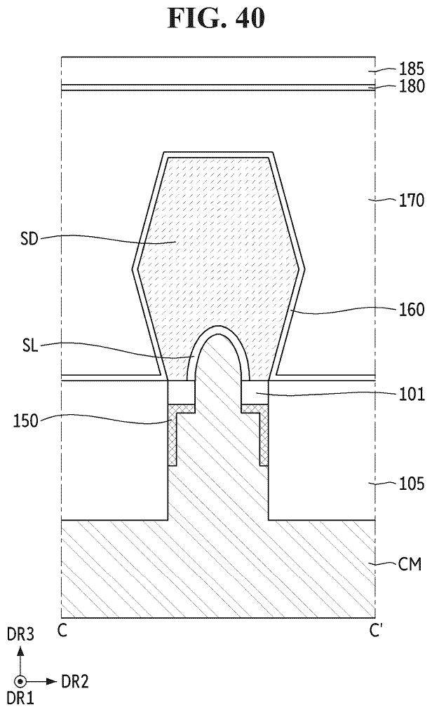

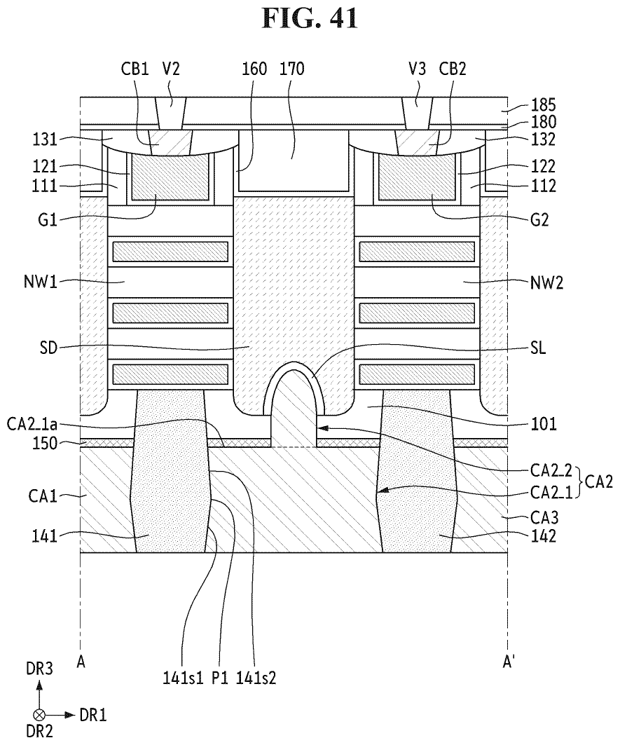

Referring to FIGS. 41 to 43, a portion of the contact material layer CM (see FIGS. 38 to 40), a portion of the first isolation material layer 141M (see FIGS. 38 and 39), and a portion of the second isolation material layer 142M (see FIG. 38) may be etched by performing a planarization process. After the planarization process is performed, the field insulating layer 105 may be exposed. For example, after the planarization process is performed, the remaining contact material layer CM (see FIGS. 38 and 40) may be defined as the first to third source/drain contacts CA1, CA2, CA3, the remaining first isolation material layer 141M (see FIGS. 38 and 39) may be defined as the first contact isolation layer 141, and the remaining second isolation material layer 142M (see FIG. 38) may be defined as the second contact isolation layer 142.

Referring to FIGS. 2 to 4, the lower interlayer insulating layer 100 may be formed on the lower surface of each of the first to third source/drain contacts CA1, CA2, CA3, the first and second contact isolation layers 141, 142, and the field insulating layer 105. Subsequently, the first via V1 connected to the second source/drain contact CA2 may be formed by penetrating or extending into the lower interlayer insulating layer 100 in the vertical direction DR3. Through such a fabrication process, the semiconductor device shown in FIGS. 2 to 4 may be fabricated.

In the method of fabricating a semiconductor device according to some embodiments of the present disclosure, the first contact isolation layer 141 may be formed on the lower part of the first gate electrode G1, the second contact isolation layer 142 may be formed on the lower part of the second gate electrode G2, and a source/drain contact CA2 may be formed between the first contact isolation layer 141 and the second contact isolation layer 142. In the method of fabricating a semiconductor device according to some embodiments of the present disclosure, a portion of the sidewalls of the first contact isolation layer 141 and a portion of the sidewalls of the second contact isolation layer 142 may be etched, respectively, to prevent a void from being formed between the first contact isolation layer 141 and the second contact isolation layer 142 in the process in which the source/drain contact CA2 is formed. As a result, the method of fabricating a semiconductor device according to some embodiments of the present disclosure may improve the reliability of the source/drain contact CA2.

In the semiconductor device according to some embodiments of the present disclosure fabricated by the method of fabricating the semiconductor device as described above, the slope profile of the first sidewall 141s1 of the first contact isolation layer 141 and the slope profile of the second sidewall 141s2 of the first contact isolation layer 141 may be formed differently based on the vertex P1. Further, the sidewall of the first contact isolation layer 141 in the first horizontal direction DR1 may be in contact with each of the liner layer 150 and the active pattern 101.

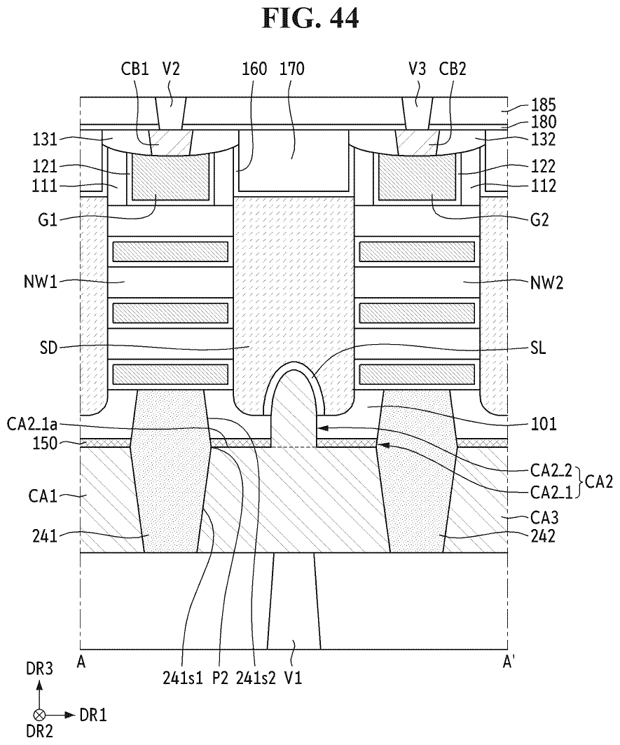

Hereinafter, with reference to FIG. 44, a semiconductor device according to several embodiments of the present disclosure will be described. The description will focus on differences from the semiconductor device shown in FIGS. 1 to 4.

FIG. 44 is a cross-sectional view for explaining a semiconductor device according to some embodiments of the present disclosure.

Referring to FIG. 44, in a semiconductor device according to some embodiments of the present disclosure, the vertex P2 of the first contact isolation layer 241 may be formed on the interface between the upper surface CA2_1a of the first portion CA2_1 of the second source/drain contact CA2 and the lower surface of the liner layer 150.

For example, the first sidewall 241s1 of the first contact isolation layer 241 may be in contact with the sidewall of the first portion CA2_1 of the second source/drain contact CA2 in the first horizontal direction DR1. The second sidewall 241s2 of the first contact isolation layer 241 may be in contact with each of the liner layer 150 and the active pattern 101. For example, the slope profile of the first sidewall 241s1 of the first contact isolation layer 241 and the slope profile of the second sidewall 241s2 of the first contact isolation layer 241 may be formed differently based on the vertex P2. The second contact isolation layer 242 may be spaced apart from the first contact isolation layer 241 in the first horizontal direction DR1. The shape of the sidewalls of the second contact isolation layer 242 may be the same as the shape of the sidewalls of the first contact isolation layer 241.

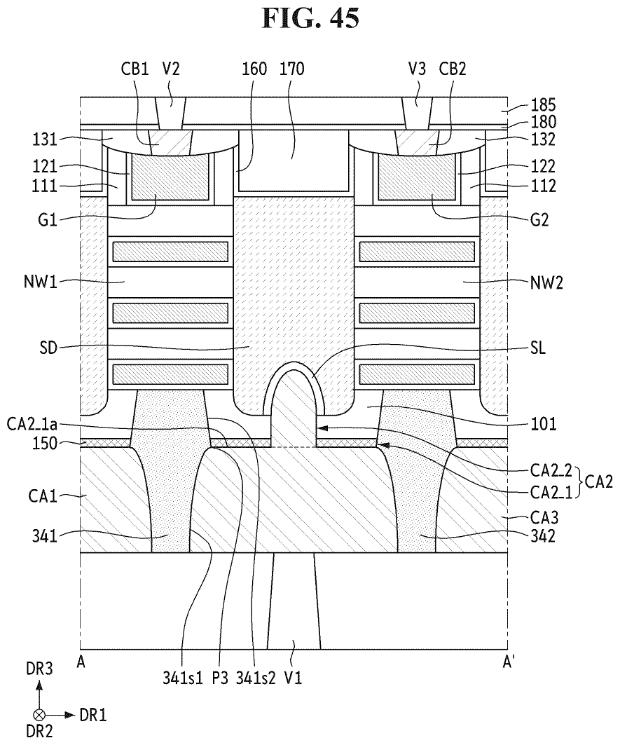

Hereinafter, with reference to FIG. 45, a semiconductor device according to some embodiments of the present disclosure will be described. The description will focus on differences from the semiconductor device shown in FIGS. 1 to 4.

FIG. 45 is a cross-sectional view for explaining a semiconductor device according to some embodiments of the present disclosure.

Referring to FIG. 45, in a semiconductor device according to some embodiments of the present disclosure, the first sidewall 341s1 of the first contact isolation layer 341 may be formed concavely (e.g., has a concave shape) toward the center of the first contact isolation layer 341.

For example, both sidewalls of the first contact isolation layer 341 in the first horizontal direction DR1 may be formed concavely (e.g., has a concave shape) toward the center of the first contact isolation layer 341 on the lower surface of the liner layer 150. For example, the first sidewall 341s1 of the first contact isolation layer 341 may be in contact with the sidewall of the first portion CA2_1 of the second source/drain contact CA2 in the first horizontal direction DR1. The second sidewall 341s2 of the first contact isolation layer 341 may be in contact with each of the liner layer 150 and the active pattern 101. For example, the slope profile of the first sidewall 341s1 of the first contact isolation layer 341 and the slope profile of the second sidewall 341s2 of the first contact isolation layer 341 may be formed differently based on the vertex P3, which may also be an inflection point of the first contact isolation layer 341. The second contact isolation layer 342 may be spaced apart from the first contact isolation layer 341 in the first horizontal direction DR1. The shape of the sidewalls of the second contact isolation layer 342 may be the same as the shape of the sidewalls of the first contact isolation layer 341.

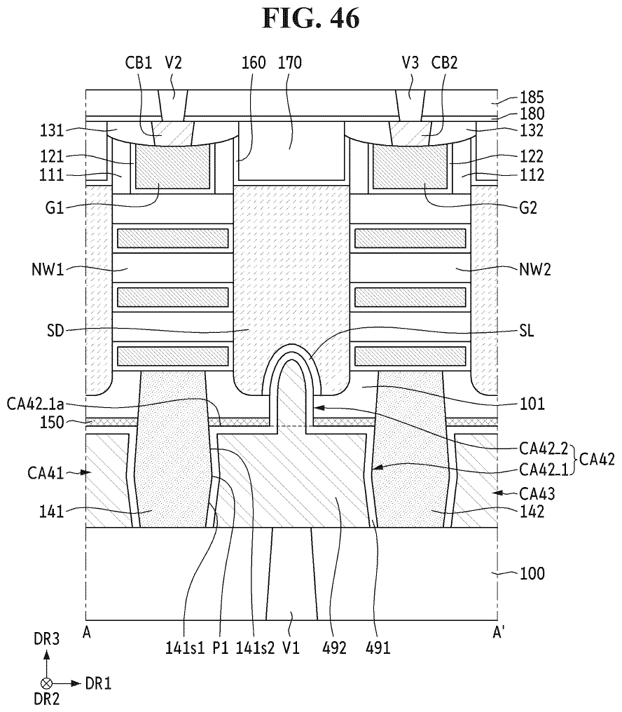

Hereinafter, with reference to FIG. 46, a semiconductor device according to some embodiments of the present disclosure will be described. The description will focus on differences from the semiconductor device shown in FIGS. 1 to 4.

FIG. 46 is a cross-sectional view for explaining a semiconductor device according to some embodiments of the present disclosure.

Referring to FIG. 46, in a semiconductor device according to some embodiments of the present disclosure, each of the first to third source/drain contacts CA41, CA42, CA43 may be formed as a double layer.

For example, the second source/drain contact CA42 may include the contact barrier layer 491 and the contact filling layer 492. The contact barrier layer 491 may form a portion of the sidewalls and upper surface of the first portion CA42_1 of the second source/drain contact CA42. Further, the contact barrier layer 491 may form the sidewalls and upper surface of the second portion CA42_2 of the second source/drain contact CA42. That is, the contact barrier layer 491 may extend along or be on an edge of the second source/drain contact CA42. For example, the contact barrier layer 491 may be in contact with the sidewalls of each of the first contact isolation layer 141 and the second contact isolation layer 142 in the first horizontal direction DR1. For example, the upper surface CA42_1a of the first portion CA42 of the second source/drain contact CA42 may be in contact with the lower surface of the liner layer 150. In other words, the contact barrier layer 491 may be in contact with the lower surface of the liner layer 150. In addition, the contact barrier layer 491 may be in contact with both sidewalls of each of the liner layer 150 and the active pattern 101 in the first horizontal direction DR1. For example, the contact filling layer 492 may fill or be in the gap between the contact barrier layer 491.

For example, the contact barrier layer 491 may include any one of tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), and rhodium (Rh). For example, the contact filling layer 492 may include any one of aluminum (Al), tungsten (W), cobalt (Co), ruthenium (Ru), and/or molybdenum (Mo).

While embodiments according to the present disclosure have been described above with reference to the accompanying drawings, it will be understood that the present disclosure is not limited to the above embodiments and may be fabricated in a variety of different forms, and those skilled in the art to which the present disclosure belongs, with ordinary knowledge in the field, may recognize that it may be implemented in other specific forms without changing the technical idea or essential features of the present disclosure. Therefore, it should be understood that the above-described embodiments are examples in all respects and not restrictive.

What is claimed is:

1. A semiconductor device comprising:
a lower interlayer insulating layer;
an active pattern spaced apart from an upper surface of the lower interlayer insulating layer in a vertical direction that is perpendicular to the upper surface of the lower interlayer insulating layer, the active pattern extending in a first horizontal direction that is parallel to the upper surface of the lower interlayer insulating layer, the active pattern comprising silicon (Si);
a plurality of nanosheets that are on the active pattern and spaced apart from each other in the vertical direction;
a gate electrode on the active pattern and extending in a second horizontal direction that is parallel to the upper surface of the lower interlayer insulating layer that intersects the first horizontal direction, the gate electrode surrounding at least a portion of the plurality of nanosheets;
a source/drain region that is on a first side of the gate electrode and is on the active pattern;
a liner layer in contact with a lower surface of the active pattern, the liner layer spaced apart from the upper surface of the lower interlayer insulating layer in the vertical direction, the liner layer comprising an insulating material;
a contact isolation layer on a lower part of the gate electrode, the contact isolation layer extending from the upper surface of the lower interlayer insulating layer to an uppermost surface of the active pattern in the vertical direction; and
a source/drain contact between the upper surface of the lower interlayer insulating layer and the source/drain region, the source/drain contact electrically connected to the source/drain region, the source/drain contact comprising a first portion in contact with a sidewall of the contact isolation layer in the first horizontal direction, the source/drain contact comprising a second portion extending into the source/drain region, the liner layer, and the active pattern in the vertical direction, the second portion of the source/drain contact on an upper surface of the first portion of the source/drain contact,
wherein the sidewall of the contact isolation layer comprises a first sidewall in contact with the source/drain contact in the first horizontal direction, a second sidewall in contact with each of the liner layer and the active pattern in the first horizontal direction, and a vertex between the first sidewall and the second sidewall, and
wherein a slope profile of the first sidewall of the contact isolation layer and a slope profile of the second sidewall of the contact isolation layer are different.

2. The semiconductor device of claim 1, wherein at least a portion of the upper surface of the first portion of the source/drain contact is in contact with a lower surface of the liner layer in the vertical direction.

3. The semiconductor device of claim 1, wherein at least a portion of the active pattern is between an upper surface of the liner layer and a lower surface of the source/drain region.

4. The semiconductor device of claim 1, wherein a sidewall of the second portion of the source/drain contact is in contact with each of the liner layer and the active pattern in the first horizontal direction.

5. The semiconductor device of claim 1, wherein a width of a lower surface of the second portion of the source/drain contact in the first horizontal direction is less than a width of the upper surface of the first portion of the source/drain contact in the first horizontal direction.

6. The semiconductor device of claim 1, further comprising:
a silicide layer between the source/drain contact and the source/drain region, wherein a lower surface of the silicide layer is in contact with the active pattern.

7. The semiconductor device of claim 1, wherein a height of an upper surface of the contact isolation layer relative to the upper surface of the lower interlayer insulating layer in the vertical direction is greater than a height of an upper surface of the liner layer relative to the upper surface of the lower interlayer insulating layer in the vertical direction.

8. The semiconductor device of claim 1, further comprising:
a field insulating layer that is on the upper surface of the lower interlayer insulating layer and in contact with the sidewalls of each of the contact isolation layer, the first portion of the source/drain contact, the liner layer and the active pattern in the second horizontal direction.

9. The semiconductor device of claim 8, wherein a height of an upper surface of the liner layer relative to the upper surface of the interlayer insulating layer in the vertical direction is less than a height of an upper surface of the field insulating layer relative to the upper surface of the interlayer insulating layer in the vertical direction.

10. The semiconductor device of claim 1,
wherein the vertex is on a sidewall of the first portion of the source/drain contact, and
wherein at least a portion of the second sidewall of the contact isolation layer is in contact with the sidewall of the first portion of the source/drain contact in the first horizontal direction.

11. The semiconductor device of claim 1, wherein the first sidewall of the contact isolation layer has a concave shape toward a center of the contact isolation layer.

12. The semiconductor device of claim 1, wherein the source/drain contact comprises:
a contact filling layer; and
a contact barrier layer extending along an edge of the source/drain contact,
wherein the contact barrier layer at least partially surrounds the contact filling layer, and
wherein the contact barrier layer is in contact with the sidewall of the contact isolation layer in the first horizontal direction.

13. A semiconductor device comprising:
a lower interlayer insulating layer;
an active pattern spaced apart from an upper surface of the lower interlayer insulating layer in a vertical direction that is perpendicular to the upper surface of the lower interlayer insulating layer, the active pattern extending in a first horizontal direction that is parallel to the upper surface of the lower interlayer insulating layer, the active pattern comprising silicon (Si);
a first gate electrode on the active pattern and extending in a second horizontal direction that is parallel to the upper surface of the lower interlayer insulating layer and intersects the first horizontal direction;
a second gate electrode extending in the second horizontal direction and on the active pattern, the second gate electrode spaced apart from the first gate electrode in the first horizontal direction;
a source/drain region that is between the first gate electrode and the second gate electrode and is on the active pattern;
a liner layer in contact with a lower surface of the active pattern, the liner layer spaced apart from the upper surface of the lower interlayer insulating layer in the vertical direction, the liner layer comprising an insulating material;
a first contact isolation layer on a lower part of the first gate electrode, the first contact isolation layer extending from the upper surface of the lower interlayer insulating layer to an uppermost surface of the active pattern in the vertical direction,
a second contact isolation layer on a lower part of the second gate electrode, the second contact isolation layer extending from the upper surface of the lower interlayer insulating layer to the uppermost surface of the active pattern in the vertical direction, the second contact isolation layer spaced apart from the first contact isolation layer in the first horizontal direction; and
a source/drain contact between the upper surface of the lower interlayer insulating layer and the source/drain region, the source/drain contact electrically connected to the source/drain region, the source/drain contact comprising a first portion in contact with sidewalls of each of the first contact isolation layer and the second contact isolation layer in the first horizontal direction, the source/drain contact comprising a second portion extending into the source/drain region, the liner layer, and the active pattern in the vertical direction, the second portion of the source/drain contact on an upper surface of the first portion of the source/drain contact,
wherein the sidewall of the first contact isolation layer comprises a first sidewall in contact with the source/drain contact in the first horizontal direction, a second sidewall in contact with each of the liner layer and the active pattern in the first horizontal direction, and a vertex between the first sidewall and the second sidewall,
wherein a slope profile of the first sidewall of the first contact isolation layer and a slope profile of the second sidewall of the first contact isolation layer are different, and
wherein at least a portion of the upper surface of the first portion of the source/drain contact is in contact with a lower surface of the liner layer in the vertical direction.

14. The semiconductor device of claim 13, wherein at least a portion of the active pattern is disposed between an upper surface of the liner layer and a lower surface of the source/drain region in the vertical direction.

15. The semiconductor device of claim 13, further comprising:
a first gate insulating layer between the first gate electrode and the first contact isolation layer, the first gate insulating layer in contact with an upper surface of the first contact isolation layer in the first horizontal direction; and
a second gate insulating layer between the second gate electrode and the second contact isolation layer, the second gate insulating layer in contact with an upper surface of the second contact isolation layer in the first horizontal direction.

16. The semiconductor device of claim 13, wherein a sidewall of the second portion of the source/drain contact is in contact with each of the liner layer and the active pattern in the second horizontal direction.

17. The semiconductor device of claim 13, wherein a width of a lower surface of the second portion of the source/drain contact in the second horizontal direction is less than a width of the upper surface of the first portion of the source/drain contact in the second horizontal direction.

18. The semiconductor device of claim 13, wherein a height of each of an upper surface of the first contact isolation layer and an upper surface of the second contact isolation layer relative to the upper surface of the lower interlayer insulating layer in the vertical direction is greater than a height of an upper surface of the liner layer relative to the upper surface of the lower interlayer insulating layer in the vertical direction.

19. The semiconductor device of claim 13, wherein the vertex is at an interface between the upper surface of the first portion of the source/drain contact and the lower surface of the liner layer.

20. A semiconductor device comprising:
a lower interlayer insulating layer;
an active pattern spaced apart from an upper surface of the lower interlayer insulating layer in a vertical direction that is perpendicular to the upper surface of the lower interlayer insulating layer, the active pattern extending in a first horizontal direction that is parallel to the upper surface of the lower interlayer insulating layer, the active pattern comprising silicon (Si):
a plurality of nanosheets that are on the active pattern and spaced apart from each other in the vertical direction;
a gate electrode on the active pattern and extending in a second horizontal direction that is parallel to the upper surface of the lower interlayer insulating layer and intersects the first horizontal direction, the gate electrode surrounding at least a portion of the plurality of nanosheets;
a source/drain region that is on a first side of the gate electrode and is on the active pattern;
a liner layer in contact with a lower surface of the active pattern, the liner layer spaced apart from the upper surface of the lower interlayer insulating layer in the vertical direction, the liner layer comprising an insulating material;
a gate insulating layer that is between the active pattern and the gate electrode and is between the plurality of nanosheets and the gate electrode, the gate insulating layer spaced apart from the liner layer in the vertical direction;
a contact isolation layer on a lower part of the gate electrode, the contact isolation layer extending from the upper surface of the lower interlayer insulating layer to an uppermost surface of the active pattern in the vertical direction, an upper surface of the contact isolation layer being in contact with the gate insulating layer in the vertical direction;
a source/drain contact between the upper surface of the lower interlayer insulating layer and the source/drain region, the source/drain contact electrically connected to the source/drain region, the source/drain contact comprising a first portion in contact with a sidewall of the contact isolation layer in the first horizontal direction, source/drain contact comprising a second portion extending into the source/drain region, the liner layer, and the active pattern in the vertical direction, the second portion of the source/drain contact on an upper surface of the first portion of the source/drain contact;
a silicide layer between the source/drain contact and the source/drain region, a lower surface of the silicide layer in contact with the active pattern in the vertical direction; and
a field insulating layer that is on the upper surface of the lower interlayer insulating layer and in contact with the sidewalls of each of the contact isolation layer, the first portion of the source/drain contact, the liner layer and the active pattern in the second horizontal direction,
wherein the sidewall of the contact isolation layer comprises a first sidewall in contact with the source/drain contact in the first horizontal direction, a second sidewall in contact with each of the source/drain contact, the liner layer, and the active pattern in the first horizontal direction, and a vertex between the first sidewall and the second sidewall,
wherein the vertex is on a sidewall of the first portion of the source/drain contact in the first horizontal direction,
wherein a slope profile of the first sidewall of the contact isolation layer and a slope profile of the second sidewall of the contact isolation layer are different, and
wherein at least a portion of the upper surface of the first portion of the source/drain contact is in contact with a lower surface of the liner layer in the vertical direction.
